(19) United States
(12) Patent Application Publication
(10) Pub. No.: US 2026/0265117 A1
(43) Pub. Date: Sep. 10, 2026

(54) Glass Composition, Microcrystalline Glass, Preparation Method Therefor and Application Thereof

(71) Applicant: HUNAN KIBING NEW MATERIALS CO., LTD., Liling City, Hunan Province (CN)

(72) Inventors: Xingjun XU, Shenzhen, Guangdong (CN); Wugang TAO, Shenzhen, Guangdong (CN); Chenggang YANG, Shenzhen, Guangdong (CN)

(21) Appl. No.: 18/723,362

(22) PCT Filed: Dec. 14, 2022
(86) PCT No.: PCT/CN2022/139075

§ 371 Date: Jun. 21, 2024

(30) Foreign Application Priority Data
Dec. 31, 2021 (CN) 202111681556.8
Dec. 31, 2021 (CN) 202111682722.6
Dec. 31, 2021 (CN) 202111682724.5

(51) Int. Cl. C03C 3/097; C03C 10/00; C03C 21/00; H05K 5/03

(52) U.S. Cl. CPC C03C 3/097; C03C 10/0027; C03C 21/002; H05K 5/03; C03C 2203/10; C03C 2203/52; C03C 2214/16

(57) ABSTRACT

Provided in the present application are a glass composition, microcrystalline glass and a preparation method therefor and application thereof. The glass composition includes, by mass percentage, 71.5-74.5% of SiO₂; 6.2-8.7% of Al₂O₃; 1.7-3% of P₂O₅; 10-12.5% of Li₂O; 0.1-2% of Na₂O; and 3-5% of ZrO₂. In the technical solutions of the present application, the components SiO₂, Al₂O₃, P₂O₅, Li₂O, Na₂O, and ZrO₂ in the glass composition are combined at a specific proportion, and in combination with a crystallization process and a strengthening process of microcrystalline glass, a b value and a haze can be significantly reduced, and the microcrystalline glass with excellent strengthening performance is thereby obtained.

### CROSS-REFERENCE TO RELATED APPLICATION

The present application claims priority to Chinese Patent Application No. 202111682724.5 filed on Dec. 31, 2021, claims priority to Chinese Patent Application No. 202111681556.8 filed on Dec. 31, 2021, and claims priority to Chinese Patent Application No. 202111682722.6 filed on Dec. 31, 2021, the disclosures of which are hereby incorporated by reference in their entireties.

### TECHNICAL FIELD

The present disclosure relates to the technical field of glass manufacturing, and particularly to a glass composition, microcrystalline glass and a preparation method and application thereof.

### BACKGROUND

With the development of display technologies, glass is commonly used in the protection of display devices. Cover glass used for the protection of electronic products in the market generally belongs to high aluminosilicate glass, and high aluminum facilitates the improvement of stress strength and stress layer depth after ion exchange, but the fall resistance of glass is poor. Research showed that 70% of electronic product damage is caused by inadvertent drops.

By introducing a nucleating agent in a glass formula or adjusting oxide ratio compositions in the formula, and then forming one or more crystalline phases in subsequent heat treatment processes, which is referred to as microcrystalline glass. The microcrystalline glass simultaneously has high transmittance of glass and high strength of ceramics, such that the performance of the glass such as average hardness and fracture toughness can be improved. A microcrystalline phase of the microcrystalline glass may hinder a microcrack extension path, facilitating the overall improvement of the performance of the glass such as scratch resistance, shock resistance, and drop resistance.

The performance of the microcrystalline glass depends on a ratio of a crystalline phase to a glass phase, the sizes of crystal particles, etc. During the preparation of the microcrystalline glass, the b value and haze of the transparent microcrystalline glass prepared currently are relatively large due to factors such as agglomeration of glass compositions, interface morphology of crystalline phases, crystal particle appearance, and macroscopic performance is that transmitted light is yellowish, affecting the transmittance and application performance of the microcrystalline glass.

### SUMMARY

The present disclosure is mainly intended to provide a glass composition, microcrystalline glass and a preparation method and application thereof, so as to solve the problems of the relatively-large b value and relatively-high haze of existing microcrystalline glass.

In order to implement the above objective, the present disclosure provides a glass composition, including, by mass percentage:
71.5-74.5% of SiO₂;
6.2-8.7% of Al₂O₃;
1.7-3% of P₂O₅;
10-12.5% of Li₂O;
0.1-2% of Na₂O; and
3-5% of ZrO₂.

In one embodiment, the glass composition further includes 0.1-1.7% of B₂O₃ and/or 0.1-1.5% of CaO.

In one embodiment, −1.1≤W(SiO₂)-6×W(Al₂O₃)-2×W(Li₂O)≤6.7.

In one embodiment, 0.19≤[W(Li₂O)—W(Al₂O₃)]/[W(P₂O₅)+W(ZrO₂)]≤0.98.

In one embodiment, 0.06≤[W(ZrO₂)-3×W(B₂O₃)]/W(P₂O₅)≤1.57.

In one embodiment, the glass composition includes, by mass percentage:
72-74% of SiO₂;
7.5-8.4% of Al₂O₃;
2-2.8% of P₂O₅;
0.3-0.8% of B₂O₃;
10.5-11.8% of Li₂O;
0.5-1.3% of Na₂O; and
3.4-4.7% of ZrO₂.

In one embodiment, 0.6≤W(SiO₂)-6×W(Al₂O₃)-2×W(Li₂O)≤5.4;
0.28≤[W(Li₂O)—W(Al₂O₃)]/[W(P₂O₅)+W(ZrO₂)]≤0.8; and
0.5≤[W(ZrO₂)-3×W(B₂O₃)]/W(P₂O₅)≤1.36.

In one embodiment, the glass composition includes, by mass percentage:
72.5-73.5% of SiO₂;
7.7-8% of Al₂O₃;
2.1-2.5% of P₂O₅;
0.5-0.7% of B₂O₃;
11-11.5% of Li₂O;
0.7-1.1% of Na₂O;
3.8-4.4% of ZrO₂;
In one embodiment, 2.5≤W(SiO₂)-6×W(Al₂O₃)-2×W(Li₂O)≤4.3;
0.43≤[W(Li₂O)—W(Al₂O₃)]/[W(P₂O₅)+W(ZrO₂)]≤0.64; and
0.81≤[W(ZrO₂)-3×W(B₂O₃)]/W(P₂O₅)≤1.16.

The present disclosure provides a glass composition, including, by mass percentage: 72-74.3% of SiO₂, 7-8.5% of Al₂O₃, 1.8-3% of P₂O₅, 10.2-12.5% of Li₂O, 0.5-2% of Na₂O, and 3.5-4.7% of ZrO₂.

In one embodiment, 2.9≤W(SiO₂)-6×W(Al₂O₃)-2×W(Li₂O)≤5.2;
0.26≤[W(Li₂O)—W(Al₂O₃)]/[W(P₂O₅)+W(ZrO₂)]≤0.85;
1.17≤W(ZrO₂)/W(P₂O₅)≤2.61; and
2.5≤[W(SiO₂)-6×W(Al₂O₃)-2×W(Li₂O)]/W(Na₂O)≤5.8.

In one embodiment, the glass composition includes, by mass percentage:
72.8-73.9% of SiO₂, 7.4-8% of Al₂O₃, 2.1-2.6% of P₂O₅, 10.7-11.7% of Li₂O, 0.9-1.4% of Na₂O, and 3.9-4.4% of ZrO₂.

In one embodiment, 4.5≤W(SiO₂)-6×W(Al₂O₃)-2×W(Li₂O)≤5.2;
0.42≤[W(Li₂O)—W(Al₂O₃)]/[W(P₂O₅)+W(ZrO₂)]≤0.66;
1.5≤W(ZrO₂)/W(P₂O₅)≤2.1; and
3.57≤[W(SiO₂)-6×W(Al₂O₃)-2×W(Li₂O)]/W(Na₂O)≤5.

The present disclosure provides a glass composition, including the following components by mass percentage:
71.5-74% of SiO₂, 6.2-8.5% of Al₂O₃, 1.7-2.6% of P₂O₅, 0.1-1.7% of B₂O₃, 10-12% of Li₂O, 0.1-2% of Na₂O, 0.1-1.5% of CaO, and 3-5% of ZrO₂.

In one embodiment, the glass composition includes the following components by mass percentage based on oxides:
72-73.5% of SiO₂, 6.8-8.2% of Al₂O₃, 2-2.4% of P₂O₅, 0.4-1.1% of B₂O₃, 10.8-11.7% of Li₂O, 0.4-1.7% of Na₂O, 0.3-1% of CaO, and 3.3-4.4% of ZrO₂.

In one embodiment, 2≤[W(ZrO₂)—W(CaO)]/[W(P₂O₅)—W(B₂O₃)]≤3.22.

In one embodiment, 2.06≤[W(ZrO₂)—W(CaO)]/[W(P₂O₅)—W(B₂O₃)]≤2.31.

In one embodiment, 2.3≤W(SiO₂)-6×W(Al₂O₃)-2×W(Li₂O)≤10.3; and 0.27≤[W(Li₂O)—W(Al₂O₃)]/[W(P₂O₅)+W(ZrO₂)]≤0.87.

In one embodiment, 2.7≤W(SiO₂)-6×W(Al₂O₃)-2×W(Li₂O)≤7.8; and 0.46≤[W(Li₂O)—W(Al₂O₃)]/[W(P₂O₅)+W(ZrO₂)]≤0.77.

The present disclosure further provides a microcrystalline glass, including the glass composition as described above.

In one embodiment, a thickness of the microcrystalline glass is 0.3-1.5 mm.

The present disclosure further provides a microcrystalline glass, including the glass composition as described above, and the microcrystalline glass contains a crystalline phase Li₂Si₂O₅ and a crystalline phase LiAISi₄O₁₀.

In one embodiment, 0.91≤W(Li₂Si₂O₅)/W(LiAISi₄O₁₀)≤1.06.

In one embodiment, 0.97≤W(Li₂Si₂O₅)/W(LiAISi₄O₁₀)≤1.03.

In one embodiment, 10.44≤M≤12.54; and

$$M = 1.3 \times [ W ( {Li}_{2} {Si}_{2} {O}_{5} ) / W ( {LiAlSi}_{4} {O}_{10} ) ] \times \{ 0.86 \times [ W ( {SiO}_{2} ) - 6 \times W ( {Al}_{2} {O}_{3} ) - 2 \times W ( {Li}_{2} O ) ] + 1.83 \times [ ( W ( {Li}_{2} {O}_{5} ) - W ( {Al}_{2} {O}_{3} ) ) / ( W ( {P}_{2} {O}_{5} ) + W ( {ZrO}_{2} ) ) ] + 1.67 \times [ W ( {ZrO}_{2} ) / W ( {P}_{2} {O}_{5} ) ] + 0.25 \times [ ( W ( {SiO}_{2} ) - 6 \times W ( {Al}_{2} {O}_{3} ) - 2 \times W ( {Li}_{2} O ) ) / W ( {Na}_{2} O ) ] \} .$$

In one embodiment, 11.85≤M≤12.54.

The present disclosure further provides a microcrystalline glass, including the glass composition as described above.

In one embodiment, a crystalline phase of the microcrystalline glass mainly is a lithium disilicate and a petalite, and a total content of the crystalline phase of the microcrystalline glass is 60%-90%, a content of the lithium disilicate is greater than 30%, and a content of the petalite is greater than 30%.

The present disclosure further provides a method for preparing a microcrystalline glass, including the following steps.

At S10, the glass composition as described above is weighed.

At S20, the glass composition is mixed, melted, clarified, homogenized, molded, annealed and finally cut to obtain a basic glass.

At S30, heat treatment is performed on the basic glass to obtain the microcrystalline glass.

In one embodiment, S30 includes the following operations.

The basic glass is heated from a room temperature to 510-540° C. in 20-60 min, and a first nucleation treatment is performed, where a time for the first nucleation treatment is 3-8 h.

A temperature is heated to 580-610° C. in 5-30 min, and a second nucleation treatment is performed, where a time for the second nucleation treatment is 3-8 h.

The temperature is heated to 650-680° C. in 5-30 min, and a crystallization treatment is performed, where a time for the crystallization treatment is 3-8 h.

The temperature is cooled to the room temperature to obtain the microcrystalline glass.

In one embodiment, the step of performing heat treatment on the basic glass to obtain the microcrystalline glass includes the following operations.

The basic glass is heated from the room temperature to 530-570° C. in 20-60 min, and nucleation treatment is performed for over 3 h.

A temperature is heated to 680-720° C. in 5-30 min, and the crystallization treatment is performed for over 3 h.

The temperature is cooled to the room temperature to obtain the microcrystalline glass. In one embodiment, after S30, the method further includes the following step.

At S40, the microcrystalline glass is pre-treated, and then placed into an ion exchange bath for a salt bath, so as to obtain a chemically-strengthened microcrystalline glass.

The ion exchange bath includes, by mass percentage, 20-40% of NaNO₃ and 60-80% of KNO₃; and/or,

A strengthening temperature of the salt bath is 420-500° C.; and/or A strengthening time of the salt bath is 3-8 h.

In one embodiment, in S20, a molding method includes a float molding, an overflow molding, a calendaring molding, or a slit pull-down molding.

The present disclosure further provides an electronic display terminal, including the microcrystalline glass as described above.

In the technical solutions of the present disclosure, the components SiO₂, Al₂O₃, P₂O₅, Li₂O, Na₂O, and ZrO₂ in the glass composition are combined at a specific proportion, and in combination with a crystallization process and a strengthening process of the microcrystalline glass, a b value and a haze can be significantly reduced, and the microcrystalline glass with excellent strengthening performance is thereby obtained.

### BRIEF DESCRIPTION OF THE DRAWINGS

In order to more clearly illustrate the embodiments of the present disclosure or the technical solutions in the prior art, the drawings used in the description of the embodiments or the prior art will be briefly described below. It is apparent that the drawings in the following descriptions are merely some embodiments of the present disclosure. Other related drawings may also be obtained from those skilled in the art according to these drawings without any creative work.

FIG. 1 is a flowchart of one embodiment of a method for preparing the microcrystalline glass according to the present disclosure.

FIG. 2 is a flowchart of another embodiment of a method for preparing the microcrystalline glass according to the present disclosure.

FIG. 3 is a diagram of a linear relationship between M and fracture toughness KIC of the microcrystalline glass in the present disclosure.

The objective implementation, functional features and advantages of the present disclosure will be further described in combination with the embodiments and with reference to the drawings.

### DETAILED DESCRIPTION OF THE EMBODIMENTS

In order to make the purposes, technical solutions and advantages of the embodiments of the present disclosure clearer, the technical solutions in the embodiments of the present disclosure will be clearly and completely described below. It is apparent that the described embodiments are only part of the embodiments of the present disclosure, not all the embodiments.

It is to be noted that, if specific conditions are not indicated in the embodiments, the implementations are carried out in accordance with the conventional conditions or the conditions recommended by manufacturers. Reagents or instruments used are conventional products that may be purchased commercially if the manufacturers are not specified. In addition, the meaning of “and/or” as it appears throughout the specification includes three concurrent solutions, including, for example, “A and/or B”, which includes solution A, or solution B, or solutions A and B that are both met. Furthermore, the technical solutions between the various embodiments may be combined with each other, but it must be based on the fact that those of ordinary skill is able to realize it, and when the combination of the technical solutions appears to be contradictory or unattainable, it should be considered that the combination of such technical solutions does not exist, and is not within the scope of protection claimed in the present disclosure. All other embodiments obtained by those of ordinary skill in the art on the basis of the embodiments in the present disclosure without creative work all fall within the scope of protection of the present disclosure.

With the development of display technologies, glass is commonly used in the protection of display devices. Cover glass used for the protection of electronic products in the market generally belongs to high aluminosilicate glass, and high aluminum facilitates the improvement of stress strength and stress layer depth after ion exchange, but the fall resistance of glass is poor. Research showed that 70% of electronic product damage is caused by inadvertent drops.

By introducing a nucleating agent in a glass formula or adjusting oxide ratio compositions in the formula, and then forming one or more crystalline phases in subsequent heat treatment processes, which is referred to as microcrystalline glass. The microcrystalline glass simultaneously has high transmittance of glass and high strength of ceramics, such that the performance of the glass such as average hardness and fracture toughness can be improved. A microcrystalline phase of the microcrystalline glass may hinder a microcrack extension path, facilitating the overall improvement of the performance of the glass such as scratch resistance, shock resistance, and drop resistance.

The performance of the microcrystalline glass depends on a ratio of a crystalline phase to a glass phase, the sizes of crystal particles, etc. During the preparation of the microcrystalline glass, the b value and haze of the transparent microcrystalline glass prepared currently are relatively large due to factors such as agglomeration of glass compositions, interface morphology of crystalline phases, crystal particle appearance, and macroscopic performance is that transmitted light is yellowish, affecting the transmittance and application performance of the microcrystalline glass.

In view of this, the present disclosure provides a glass composition. Microcrystalline glass prepared by the glass composition is able to effectively solve the problems of the relatively-large b value and relatively-high haze of existing microcrystalline glass.

An embodiment of the present disclosure provides a glass composition, including, by mass percentage, 71.5-74.5% of SiO₂; 6.2-8.7% of Al₂O₃; 1.7-3% of P₂O₅; 10-12.5% of Li₂O; 0.1-2% of Na₂O; and 3-5% of ZrO₂.

In another embodiment, the glass composition further includes, by mass percentage, 0.1-1.7% of B₂O₃ and/or 0.1-1.5% of CaO.

An embodiment of the present disclosure provides a glass composition, including, by mass percentage, 71.5-74.5% of SiO₂; 7.3-8.7% of Al₂O₃; 1.7-3% of P₂O₅; 0.1-1% of B₂O₃; 10.2-12% of Li₂O; 0.4-1.5% of Na₂O; and 3.1-5% of ZrO₂.

An embodiment of the present disclosure provides a glass composition, including, the following components by mass percentage based on oxides: 71.5-74% of SiO₂, 6.2-8.5% of Al₂O₃, 1.7-2.6% of P₂O₅, 0.1-1.7% of B₂O₃, 10-12% of Li₂O, 0.1-2% of Na₂O, 0.1-1.5% of CaO, and 3-5% of ZrO₂.

The present disclosure provides a glass composition. Microcrystalline glass prepared by the glass composition is able to effectively solve the problems of a relatively-large b value and a relatively-high haze, and a reduced crystal content and a damaged interlocking structure of two crystalline phases during a chemical strengthening process.

The glass composition includes the following components by mass percentage: 72-74.3% of SiO₂, 7-8.5% of Al₂O₃, 1.8-3% of P₂O₅, 10.2-12.5% of Li₂O, 0.5-2% of Na₂O, and 3.5-4.7% of ZrO₂.

First, it is to be noted that, as expected in the present disclosure, a molecular formula of petalite in the crystalline phase of the microcrystalline glass is LiAISi₄O₁₀, and a molecular formula of lithium disilicate is Li₂Si₂O₅. The mass percentage of each component is calculated based on the sum of the mass of SiO₂, Al₂O₃, P₂O₅, B₂O₃, Li₂O, Na₂O, and ZrO₂ in the glass composition, or based on the sum of the mass of SiO₂, Al₂O₃, P₂O₅, Li₂O, Na₂O, ZrO₂ in the glass composition.

The SiO₂ introduced in the glass composition of the present disclosure is a component constituting a glass frame. The SiO₂ may be used as a main body of a glass network structure, and empowers basic glass and microcrystalline glass with good chemical stability, mechanical properties, and molding properties. In a glass microcrystallization process, a SiO₂ source is provided to form Li₂Si₂O₅ and LiAISi₄O₁₀ crystalline phases. In the glass microcrystallization process, quartz and a quartz solid solution appear in the glass microcrystallization process due to excessive SiO₂. Therefore, taking all factors into consideration, the content of SiO₂ is selected from 71.5 wt % to 74.5 wt %, or the content of SiO₂ is selected from 72 wt % to 74.3 wt %, or the content of SiO₂ is selected from 71.5 wt % to 74 wt %.

The Al₂O₃ introduced in the glass composition of the present disclosure belongs to a network intermediate oxide. Non-bridging oxygen and Al form an aluminum oxide tetrahedron, a volume is greater than that of a silicon-oxygen tetrahedron, a larger slit is generated in a glass structure, facilitating ion exchange, thus achieving a better chemical strengthening effect and improving the mechanical property of glass. However, the Al₂O₃ belongs to an extremely refractory oxide, which can rapidly increase high temperature viscosity of the glass, leading to increased difficulty in clarifying and homogenizing the glass, resulting in a large increase in the concentration of bubble defects in the glass. If the content of Al₂O₃ is too high, a glass microcrystallization temperature significantly increases, such that the crystallization ability of the basic glass is inhibited, and lithium disilicate is difficult to form. During the promotion of crystallization, LiAISi₄O₁₀ is excessively formed in the glass, and even a LiAISi₂O₆ crystalline phase is formed in the basic glass, causing the transmittance of the glass to reduce. Therefore, taking all factors into consideration, the content of Al₂O₃ is selected from 7.3 wt % to 8.7 wt %, or the content of Al₂O₃ is selected from 6.2 wt % to 8.5 wt %, or the content of Al₂O₃ is selected from 7 wt % to 8.5 wt %.

The P₂O₅ is introduced in the glass composition of the present disclosure, the P₂O₅ is more favored to induce precipitation of lithium disilicate crystals. A P⁵⁺ ion has a very large field strength, strong oxygen capture ability, and a phosphorus-oxygen network structure tends to be strong and solid. Since the field strength of the P⁵⁺ ion is greater than that of a Si⁴⁺ ion, the P⁵⁺ ion is easy to separate from a network by combining with an alkali metal ion, so as to form a crystal nucleus, such that phase splitting is induced in the basic glass, reducing nucleation activation energy, thereby facilitating the crystallization of the glass. Li₂O and P₂O₅ react to form a Li₃PO₄ crystalline phase, the Li₂O and the SiO₂ in the glass are induced to react to form Li₂SiO₃, and finally, the Li₂Si₂O₅ crystalline phase is formed. In addition, the P₂O₅ is connected to form a network with a [PO₄]tetrahedron, causing the glass network structure to show a loose state, such that a network gap becomes larger, facilitating mutual diffusion of Na⁺ ions in the glass and K⁺ ions in a fused salt, and ion strengthening plays a role in promoting a glass strengthening process, and plays an important role in obtaining a high compression stress layer. However, due to excess content of the P₂O₅, precipitation of lithium metasilicate is promoted during a crystallization process, resulting in too few glass phases, such that sufficient Li₂Si₂O₅ crystalline phase cannot be formed, and crystallized glass with high transmittance is difficult to obtain due to the promoted precipitation of a quartz phase. Therefore, taking all factors into consideration, the content of P₂O₅ is selected from 1.7 wt % to 3 wt %, or the content of P₂O₅ is selected from 1.8 wt % to 3 wt %, or the content of P₂O₅ is selected from 1.7 wt % to 2.6 wt %.

The B₂O₃ is introduced in the glass composition of the present disclosure, the addition of the B₂O₃ may improve the meltability of the glass and reduce a melting point, and is conductive to improving scratch resistance of glass surfaces. Research of the present disclosure found that, the B₂O₃ is present in the form of dense [BO₄] in a microcrystalline glass structure, which may effectively inhibit the growth of the petalite to further cause large haze in the microcrystalline glass caused during the nucleation of lithium disilicate (>580° C.). In another aspect, the migration of alkali metal ions in the microcrystalline glass is limited to stabilize the microcrystalline glass structure. Therefore, taking all factors into consideration, the content of B₂O₃ is selected from 0.1 wt % to 1.7 wt %, or the content of B₂O₃ is selected from 0.1 wt % to 1 wt %.

The Li₂O introduced in the glass composition of the present disclosure belongs to a network extracorporeal oxide, which reduces the viscosity of the glass and promotes the melting and clarification of the glass. Li⁺ is a main exchange ion during a chemical strengthening treatment process. The Lit ion is small in radius, such that an ion exchange speed of the glass containing Lit is faster, and the glass obtains a thicker strengthened layer with a short time. The Lit ion exchanges with a Na⁺ ion in molten liquid, and has a faster speed than an exchange speed of Na⁺ and K⁺ ions. A high Li₂O concentration promotes the formation of Li₃PO₄ in a basic microcrystallization process, facilitating the formation of a lithium disilicate crystalline phase and a petalite crystalline phase. In order to cause the microcrystalline glass to obtain an ion strengthening degree with a high depth, sufficient Li⁺ must be available for mutual strengthening with Na⁺ during the chemical strengthening process, so as to reduce cracks on the surface of the crystallized glass, thus providing a mechanical strength effect of the microcrystallization process. However, if the Li₂O is too high, the viscosity of the glass is too low, such that it is difficult to obtain chemically-stable glass components, simultaneously causing a compression stress value during an ion strengthening process to be too low, and leading to an increase in raw material cost. Therefore, taking all factors into consideration, the content of Li₂O is selected from 10.2 wt % to 12 wt %, or the content of Li₂O is selected from 10.2 wt % to 12.5 wt %, or the content of Li₂O is selected from 10 wt % to 12 wt %.

The Na₂O introduced in the glass composition of the present disclosure is able to significantly reduce the viscosity of the basic glass, promote the melting and clarification of the basic glass, and reduce a glass crystallization temperature at the same time. The crystallized glass can be strengthened with K⁺ ions in a potassium nitrate molten salt, so as to generate high compression stress on the glass surface to improve glass strength, and sufficient Na⁺ must be available in the glass. Therefore, taking all factors into consideration, the content of Na₂O is selected from 0.1 wt % to 2 wt %, or the content of Na₂O is selected from 0.4 wt % to 1.5 wt %, or the content of Na₂O is selected from 0.5 wt % to 2 wt %.

The ZrO₂ is introduced in the glass composition of the present disclosure. In one aspect, zirconium ions have high potential energy and may enhance the glass network structure, and the ZrO₂ is more favorable to induce precipitation of petalite crystals. In another aspect, the ZrO₂ facilitates the reduction in the sizes of crystal particles during the crystallization process, thus increasing the transmittance of the glass and rapidly improving the chemical stability of the glass. Next, the fracture toughness and bending strength of the glass are improved, crystalline phase transition of zirconia may produce stress induction and improve fracture toughness after crystallization. Excessive ZrO₂ content leads to the presence of a ZrO₂ unmelted material in the glass, which results in the inability of the glass to precipitate crystals uniformly. Therefore, taking all factors into consideration, the content of ZrO₂ is selected from 3 wt % to 5 wt %, or the content of ZrO₂ is selected from 3.1 wt % to 5 wt %, or the content of ZrO₂ is selected from 3.5 wt % to 4.7 wt %.

In the technical solutions of the present disclosure, the components SiO₂, Al₂O₃, P₂O₅, B₂O₃, Li₂O, Na₂O, and ZrO₂ in the glass composition are combined at a specific proportion, and in combination with a crystallization process and a strengthening process of microcrystalline glass, a b value and a haze can be significantly reduced, and the microcrystalline glass with excellent strengthening performance is thereby obtained.

In addition, the chemical stability and mechanical strength of the glass can be improved by introducing the CaO in the glass composition of the present disclosure. Since the CaO binds acid Al₂O₃ more easily in the glass structure, affecting a coordination state of boron. In addition, the alkalinity of the CaO is greater than that of the Na₂O, such that negative charges carried by [AlO₄] tetrahedron may be compensated to stabilize a crystalline phase in the microcrystalline glass. However, high CaO content causes a decrease in devitrification resistance. Therefore, taking all factors into consideration, the content of CaO is selected from 0.1 wt % to 1.5 wt %.

In the technical solutions of the present disclosure, the components SiO₂, Al₂O₃, P₂O₅, B₂O₃, Li₂O, Na₂O, CaO, and ZrO₂ in the glass composition are combined at a specific proportion, and in combination with a crystallization process and a strengthening process of microcrystalline glass, situations of a reduced crystal content and a damaged interlocking structure of two crystalline phases during a chemical strengthening process can be significantly improved, thereby obtaining microcrystalline glass with excellent strengthening performance.

In one embodiment, the components in the glass composition include SiO₂, Al₂O₃, P₂O₅, Li₂O, Na₂O, and ZrO₂, and various components in the glass composition meet: 2.9≤W(SiO₂)-6×W(Al₂O₃)-2×W(Li₂O)≤5.2, recorded as A=W(SiO₂)-6×W(Al₂O₃)-2×W(Li₂O), where W represents a mass percentage of the component in the sum of the mass of all oxide components, and an A value is a numerator value of the mass percentage calculated by the formula. If the A value is low, the SiO₂ all enters the crystalline phase, and accordingly there is an excess of Al₂O₃ or Li₂O; and if the A value is too high, the Al₂O₃ or Li₂O all enter the crystalline phase, the remaining SiO₂ exists as a network skeleton structure in a glass phase, and a total crystalline phase content of the microcrystalline glass is low. Therefore, by controlling the A value within the above range, excess Al₂O₃ or Li₂O is avoided, such that the total crystalline phase content of the microcrystalline glass is effectively increased. Preferably, 4.5≤W(SiO₂)-6×W(Al₂O₃)-2×W(Li₂O)≤5.2.

Various components in the glass composition meet: 0.26≤[W(Li₂O)—W(Al₂O₃)]/[W(P₂O₅)+W(ZrO₂)]≤0.85, recorded as B=[W(Li₂O)—W(Al₂O₃)]/[W(P₂O₅)+W(ZrO₂)], where W represents a mass percentage of the component in the sum of the mass of all oxide components. If a B value is too low, unexpected crystalline phases such as β-quartz are easily produced, the formation proportion of the petalite crystalline phase is high, and crystal particles are easy to grow, resulting in translucent or even opaque microcrystalline proportions. If a B value is too high, the proportion of the glass phase in the microcrystalline glass increases, and the performance advantages of the microcrystalline glass cannot be fully achieved. Therefore, by controlling the B value within the above range, the performance advantages of the microcrystalline glass are fully achieved, such that translucent or even opaque microcrystalline proportions of the microcrystalline glass is avoided. Preferably, 0.42≤[W(Li₂O)—W(Al₂O₃)]/[W(P₂O₅)+W(ZrO₂)]≤0.66.

Various components in the glass composition meet: 1.17≤W(ZrO₂)/W(P₂O₅)≤2.61, recorded as C₁=W(ZrO₂)/W(P₂O₅), where W represents a mass percentage of the component in the sum of the mass of all oxide components. By controlling the C₁ value within the above range, the activation energy of a liquid-liquid surface reduces to make it split into phases, such that nucleation and precipitation of crystals may be realized at low temperatures. Therefore, liquid-phase crystallization and unstable decomposition lead to the development of phase interfaces, the activation energy or energy barrier for nucleation reduces to lower a nucleation temperature and a precipitation temperature. The two crystalline phases compete for a silicon source and a lithium source, i.e., destroying the structure of the crystalline phase already formed by the other phase in order to form its own phase, crystalline phase amounts of the formed petalite and lithium disilicate are close to each other (W(Li₂Si₂O₅)/W(LiAISi₄O₁₀)=0.91-1.06, details are described below), the sizes of the crystals are uniform and <100 nm, meeting basic requirements for optical visibility. If the C₁ value is too high or too low, an increase in a single crystalline phase is caused and easy to grow, microcrystalline visible light transmittance decreases, and the haze increases. Preferably, 1.5≤W(ZrO₂)/W(P₂O₅)≤2.1.

Various components in the glass composition meet: 2.5≤[W(SiO₂)-6×W(Al₂O₃)-2×W(Li₂O)]/W(Na₂O)≤5.8, recorded as D=[W(SiO₂)-6×W(Al₂O₃)-2×W(Li₂O)]/W(Na₂O), where W represents a mass percentage of the component in the sum of the mass of all oxide components. By controlling a D value within the above range, a glass crystalline structure is stabilized, in particular, in the strengthening process, the migration of lithium ions is inhibited. The interlocking structure formed by the petalite and the lithium disilicate of the microcrystalline glass is further maintained, so as to improve the performance of the microcrystalline glass. If the D value is too high, the chemically strengthened ions of the microcrystalline glass are difficult to exchange; and if the D value is too low, the interlocking structure formed by the petalite and the lithium disilicate of the microcrystalline glass cannot be maintained, and the microcrystalline structure is damaged during the chemical strengthening process. Preferably, 3.57≤[W(SiO₂)-6×W(Al₂O₃)-2×W(Li₂O)]/W(Na₂O)≤5.

In one embodiment, preferably, various components in the glass composition meet the following conditions: SiO₂ is 72.8-73.9%, Al₂O₃ is 7.4-8%, P₂O₅ is 2.1-2.6%, LiZO is 10.7-11.7%, Na₂O is 0.9-1.4%, and ZrO₂ is 3.9-4.4%. The performance of the microcrystalline glass obtained by the glass composition is further optimized.

In one embodiment, the components in the glass composition include SiO₂, Al₂O₃, P₂O₅, B₂O₃, Li₂O, Na₂O, and ZrO₂, and various components in the microcrystalline glass meet: −1.1≤W(SiO₂)-6×W(Al₂O₃)-2×W(Li₂O)≤6.7, recorded as A=W(SiO₂)-6×W(Al₂O₃)-2×W(Li₂O), where W represents a mass percentage of the component in the sum of the mass of all components, and an A value is a numerator value of the mass percentage calculated by the formula. If the A value is too low, the SiO₂ all enters the crystalline phase, and accordingly there is an excess of Al₂O₃ or Li₂O; the formation proportion of the petalite crystalline phase is high, and crystal particles are easy to grow, resulting in translucent or even opaque microcrystalline proportions. If the A value is too high, the Al₂O₃ or Li₂O all enter the crystalline phase, the remaining SiO₂ exists as a network skeleton structure in a glass phase, and a total crystalline phase content of the microcrystalline glass is low. Therefore, by controlling the A value within the above range, translucent or even opaque microcrystalline proportions of the microcrystalline glass are avoided, and the total crystalline phase content of the microcrystalline glass is effectively increased.

Various components in the microcrystalline glass meet: 0.19≤[W(Li₂O)—W(Al₂O₃)]/[W(P₂O₅)+W(ZrO₂)]≤0.98, recorded as B=[W(Li₂O)—W(Al₂O₃)]/[W(P₂O₅)+W(ZrO₂)], where W represents a mass percentage of the component in the sum of the mass of all components. If the B value is too low, the proportion of the glass phase in the microcrystalline glass increases, and the performance advantages of the microcrystalline glass cannot be fully achieved. If a B value is too high, unexpected crystalline phases such as β-quartz are easily produced, the formation proportion of the petalite crystalline phase is high, and crystal particles are easy to grow, resulting in translucent or even opaque microcrystalline proportions. Therefore, by controlling the B value within the above range, the performance advantages of the microcrystalline glass are fully achieved, such that translucent or even opaque microcrystalline proportions of the microcrystalline glass is avoided.

Various components in the microcrystalline glass meet: 0.06≤[W(ZrO₂)-3×W(B₂O₃)]/W(P₂O₅)≤1.57, recorded as C₂=[W(ZrO₂)-3×W(B₂O₃)]/W(P₂O₅), where W represents a mass percentage of the component in the sum of the mass of all components. By controlling the C₂ value within the above range, the activation energy of a liquid-liquid surface reduces to make it split into phases, such that nucleation and precipitation of crystals may be realized at low temperatures. Therefore, liquid-phase crystallization and unstable decomposition lead to the development of phase interfaces, the activation energy or energy barrier for nucleation reduces to lower a nucleation temperature and a precipitation temperature. The two crystalline phases compete for a silicon source and a lithium source, i.e., destroying the structure of the crystalline phase already formed by the other phase in order to form its own phase, crystalline phase amounts of the formed petalite and lithium disilicate are close to each other, the sizes of the crystals are uniform and <100 nm, meeting basic requirements for optical visibility. If the C₂ value is too high or too low, an increase in a single crystalline phase is caused and easy to grow, microcrystalline visible light transmittance decreases, and the haze increases.

In one embodiment, preferably, various components in the glass composition meet the following conditions: SiO₂ is 72-74%; Al₂O₃ is 7.5-8.4%; P₂O₅ is 2-2.8%; B₂O₃ is 0.3-0.8%; Li₂O is 10.5-11.8%; Na₂O is 0.5-1.3%; and ZrO₂ is 3.4-4.7%. The performance of the microcrystalline glass obtained by the glass composition is further optimized.

For the proportions of various components in the glass composition, more preferably, various components in the microcrystalline glass meet: 0.6≤W(SiO₂)-6×W(Al₂O₃)-2×W(Li₂O)≤5.4; 0.28≤[W(Li₂O)—W(Al₂O₃)]/[W(P₂O₅)+W(ZrO₂)]≤0.8; and 0.5≤[W(ZrO₂)-3×W(B₂O₃)]/W(P₂O₅)≤1.36. In one embodiment, various components in the glass composition meet the following conditions: SiO₂ is 72.5-73.5%; Al₂O₃ is 7.7-8%; P₂O₅ is 2.1-2.5%; B₂O₃ is 0.5-0.7%; Li₂O is 11-11.5%; Na₂O is 0.7-1.1%; and ZrO₂ is 3.8-4.4%. The microcrystalline glass obtained by the glass composition achieves better performance.

For the proportions of various components in the glass composition, more preferably, various components in the microcrystalline glass meet: 2.5≤W(SiO₂)-6×W(Al₂O₃)-2×W(Li₂O)≤4.3; 0.43≤[W(Li₂O)—W(Al₂O₃)]/[W(P₂O₅)+W(ZrO₂)]≤0.64; and 0.81≤[W(ZrO₂)-3×W(B₂O₃)]/W(P₂O₅)≤1.16.

In one embodiment, preferably, various components in the glass composition meet the following conditions: SiO₂ is 72-73.5%, Al₂O₃ is 6.8-8.2%, P₂O₅ is 2-2.4%, B₂O₃ is 0.4-1.1%, Li₂O is 10.8-11.7%, Na₂O is 0.4-1.7%, CaO is 0.3-1%, and ZrO₂ is 3.3-4.4%. The performance of the microcrystalline glass obtained by the glass composition is further optimized.

In one embodiment, the components in the glass composition include SiO₂, Al₂O₃, P₂O₅, B₂O₃, Li₂O, Na₂O, CaO, and ZrO₂, and various components in the glass composition meet: 2.3≤W(SiO₂)-6×W(Al₂O₃)-2×W(Li₂O)≤10.3, recorded as A=W(SiO₂)-6×W(Al₂O₃)-2×W(Li₂O), where W represents a mass percentage of the component, and an A value is a numerator value of the mass percentage calculated by the formula. If the A value is too low, the SiO₂ all enters the crystalline phase, and accordingly there is an excess of Al₂O₃ or Li₂O; the formation proportion of the petalite crystalline phase is high, and crystal particles are easy to grow, resulting in translucent or even opaque microcrystalline proportions. If the A value is too high, the Al₂O₃ or Li₂O all enter the crystalline phase, the remaining SiO₂ exists as a network skeleton structure in a glass phase, and a total crystalline phase content of the microcrystalline glass is low. Therefore, by controlling the A value within the above range, translucent or even opaque microcrystalline proportions of the microcrystalline glass are avoided, and the total crystalline phase content of the microcrystalline glass is effectively increased. In one embodiment, preferably, 2.7≤W(SiO₂)-6×W(Al₂O₃)-2×W(Li₂O)≤7.8.

Various components in the glass composition meet: 0.27≤[W(Li₂O)—W(Al₂O₃)]/[W(P₂O₅)+W(ZrO₂)]≤0.87, recorded as B=[W(Li₂O)—W(Al₂O₃)]/[W(P₂O₅)+W(ZrO₂)], where W represents a mass percentage of the component. If the B value is too low, the proportion of the glass phase in the microcrystalline glass increases, and the performance advantages of the microcrystalline glass cannot be fully achieved. If a B value is too high, unexpected crystalline phases such as β-quartz are easily produced, the formation proportion of the petalite crystalline phase is high, and crystal particles are easy to grow, resulting in translucent or even opaque microcrystalline proportions. Therefore, by controlling the B value within the above range, the performance advantages of the microcrystalline glass are fully achieved, such that translucent or even opaque microcrystalline proportions of the microcrystalline glass is avoided. In one embodiment, preferably, 0.46≤[W(Li₂O)—W(Al₂O₃)]/[W(P₂O₅)+W(ZrO₂)]≤0.77.

Various components in the glass composition meet: 2≤[W(ZrO₂)—W(CaO)]/[W(P₂O₅)—W(B₂O₃)]≤3.22, recorded as C₃₌[W(ZrO₂)—W(CaO)]/[W(P₂O₅)—W(B₂O₃)], where W represents a mass percentage of the component. By controlling the C₃ value within the above range, in one aspect, the activation energy of a liquid-liquid surface reduces to make it split into phases, such that nucleation and precipitation of crystals may be realized at low temperatures; and crystalline phase amounts of the formed petalite and lithium disilicate are close to each other, the sizes of the crystals are uniform and <100 nm, meeting basic requirements for optical visibility. In another aspect, a glass crystalline structure is stabilized, in particular, in the strengthening process, the migration of lithium ions is inhibited, and the content of the chemically-strengthened microcrystalline glass is increased. In addition, if the C₃ value is too high or too low, microcrystalline visible light transmittance, the b value, and haze are affected. In one embodiment, preferably, 2.06≤[W(ZrO₂)—W(CaO)]/[W(P₂O₅)—W(B₂O₃)]≤2.31.

An embodiment of the present disclosure further provides microcrystalline glass, including the glass composition as described above. The microcrystalline glass includes all technical features of the glass composition, and thus has all technical effects brought by the glass composition, and details are not described herein again.

In one embodiment, a thickness of the microcrystalline glass is 0.3-1.5 mm. If a plate thickness of the microcrystalline glass is thinner, the microcrystalline glass may be lighter.

In one embodiment, a crystalline phase of the microcrystalline glass mainly is lithium disilicate and petalite, and the total content of the crystalline phase of the microcrystalline glass is 60%-90%, the content of the lithium disilicate is greater than 30%, and the content of the petalite is greater than 30%. By guaranteeing the lithium disilicate and the petalite to be within the range, the crystalline phase content of the microcrystalline glass is great, and the two crystalline phases are balanced in proportion, thereby achieving better strengthening performance of the microcrystalline glass.

In one embodiment, a thickness of the microcrystalline glass is 0.3-1.5 mm. If a plate thickness of the microcrystalline glass is thinner, the microcrystalline glass may be lighter.

An embodiment of the present disclosure further provides microcrystalline glass, including the glass composition as described above. The microcrystalline glass contains a crystalline phase Li₂Si₂O₅ and a crystalline phase LiAISi₄O₁₀. The microcrystalline glass includes all technical features of the glass composition, and thus has all technical effects brought by the glass composition, and details are not described herein again.

The microcrystalline glass also needs to meet: 0.91≤W(Li₂Si₂O₅)/W(LiAISi₄O₁₀)≤1.06, recorded as E=W(Li₂Si₂O₅)/W(LiAISi₄O₁₀), where W represents a mass percentage of the crystalline phase in the microcrystalline glass. By controlling the E value within the above range, crystalline phase amounts of the formed petalite and lithium disilicate are guaranteed to be close to each other, so as to further improve the performance of the microcrystalline glass. Further preferably, 0.97≤W(Li₂Si₂O₅)/W(LiAISi₄O₁₀)≤1.03.

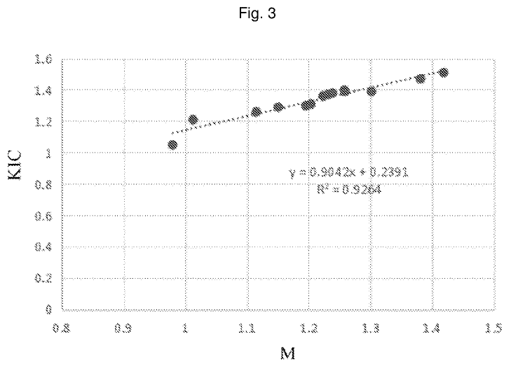

The microcrystalline glass also needs to meet: 10.44≤M≤12.54, where M=1.3×[W(Li₂Si₂O₅)/W(LiAISi₄O₁₀)]×{0.86×[W(SiO₂)-6×W(Al₂O₃)-2×W(Li₂O)]+1.83×[(W(Li₂O)—W(Al₂ O₃))/(W(P₂O₅)+W(ZrO₂))]+1.67×[W(ZrO₂)/W(P₂O₅)]+0.25×[(W(SiO₂)-6×W(Al₂O₃)-2×W(Li₂O))/W(Na₂O)]}. That is, M=1.3E×(0.86×A+1.83×B+1.67×C+0.25×D), through researches, it has found that there is a linear relationship between M and fracture toughness KIC of the microcrystalline glass, as shown in FIG. 3, according to the linear relationship, the fracture toughness of the microcrystalline glass is improved by controlling the M value within the above range. Further preferably, 11.85≤M≤12.54.

In one embodiment, a thickness of the microcrystalline glass is 0.3-1.5 mm. If a plate thickness of the microcrystalline glass is thinner, the microcrystalline glass may be lighter.

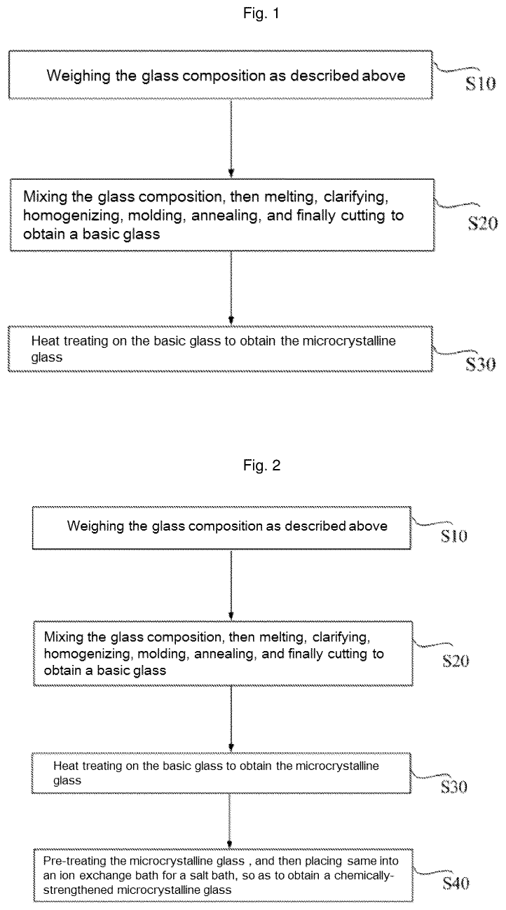

In addition, the present disclosure further provides a method for preparing microcrystalline glass, used for preparing the above microcrystalline glass. As shown in FIG. 1, the method includes the following steps.

At S10, the glass composition as described above is weighed.

At S20, the glass composition is mixed, melted, clarified, homogenized, molded, annealed and finally cut to obtain a basic glass.

Specifically, in S20, a molding method includes a float molding, an overflow molding, a calendaring molding, or a slit pull-down molding. Other processes such as clarification, homogenization, annealing, and cutting are conventional processes in the field of glass technologies, and are not described herein again. Through the above processes, the thickness of the obtained basic glass is 0.3-1.5 mm.

At S30, heat treatment is performed on the basic glass to obtain microcrystalline glass.

Specifically, S30 includes: heating the basic glass from the room temperature to 510-540° C. in 20-60 min, and performing the first nucleation treatment, where the time for the first nucleation treatment is 3-8 h; heating a temperature to 580-610° C. in 5-30 min, and performing the second nucleation treatment, where the time for the second nucleation treatment is 3-8 h; heating the temperature to 650-680° C. in 5-30 min, and performing crystallization treatment, where the time for the crystallization treatment is 3-8 h; and cooling the temperature to the room temperature to obtain the microcrystalline glass.

In one embodiment, as shown in FIG. 2, after S30, the method further includes the following step.

At S40, the microcrystalline glass is pre-treated, and then placed into an ion exchange bath for a salt bath, so as to obtain the chemically-strengthened microcrystalline glass. The ion exchange bath includes, by mass percentage, 20-40% of NaNO₃ and 60-80% of KNO₃. A strengthening temperature of the salt bath is 420-500° C. A strengthening time of the salt bath is 3-8 h.

Due to the high crystal content in the microcrystalline glass, there are structural differences between the glass phase and the crystalline phase, thereby forming structural cavities. For example, by using a molten salt containing NaNO₃>40 wt %, although Na⁺/Li⁺ may reach a deep ionic depth in a short time during ion exchange, Na⁺ tends to agglomerate in the cavities between the microcrystalline phase and the glass phase, making it difficult to form compressive stress. The Na⁺/Li⁺ exchange in the glass phase is too fast, and by then the difference between the glass phase and the microcrystalline phase further increases, easily causing an increase in the b value.

The Na⁺/Li⁺ exchange speed in the crystalline phase may be slowed down by using the above strengthening system, such that Na⁺ aggregation in the cavities between the microcrystalline phase and the glass phase is reduced, thereby effectively forming compressive stress; and the glass phase and the exchange speed may be reduced, and the difference between the glass phase and the crystalline phase is reduced, thereby further reducing the b value of the glass.

It is to be noted that, in S40, the pre-treatment step specifically includes: placing the microcrystalline glass at 300-330° C., and maintaining a reaction at the temperature for 5-20 min. The pre-treatment is a conventional means in the field of glass technologies, and is not described in detail herein.

The present disclosure further provides an electronic display terminal. The electronic display terminal includes the microcrystalline glass. Specific features of the microcrystalline glass are referred to the above embodiments. Since the current electronic display terminal uses all technical solutions of all the embodiments, the electronic display terminal has at least all beneficial effects brought by the technical solutions of the above embodiments, and details are not described herein again. The microcrystalline glass is used as cover glass or a protective part of the electronic display terminal, or the microcrystalline glass is used as cover glass of an intelligent terminal, or the microcrystalline glass is used as cover glass of solar cells.

The technical solutions of the present disclosure are described in further detail below with reference to specific embodiments and the drawings, and it is to be understood that the following embodiments are used only to explain the present disclosure and are not intended to limit the present disclosure.

### Embodiment

(1) A glass composition was weighed, and included, by mass percentage, 72% of SiO₂, 7% of Al₂O₃, 3% of P₂O₅, 12.5% of Li₂O, 2% of Na₂O, and 3.5% of ZrO₂.
(2) The glass composition was mixed, melted, clarified, homogenized, molded, annealed and finally cut to obtain a basic glass.
(3) The basic glass was heated from the room temperature to 530° C. in 20 min, nucleation treatment was performed, and the time for the first nucleation treatment was 3 h; a temperature was heated to 680° C. in 30 min, crystallization treatment was performed, and the time for the crystallization treatment was 3 h; and the temperature was cooled to the room temperature to obtain a microcrystalline glass.
(4) An ion exchange bath was provided, the ion exchange bath included, by mass percentage, 40% of NaNO₃ and 60% of KNO₃, the microcrystalline glass was pre-treated, and then placed into the ion exchange bath for a salt bath, so as to obtain the chemically-strengthened microcrystalline glass, a strengthening temperature of the salt bath was 420° C., and a strengthening time of the salt bath was 3 h.

Raw materials were weighed according to component proportions of the glass composition of various embodiments shown in Table I1 and Table I2, and the microcrystalline glass and the chemically-strengthened microcrystalline glass in other Embodiment A2 to Embodiment A14 were respectively prepared by referring to a preparation method of Embodiment A1.

Raw materials were weighed according to component proportions of the glass composition of Comparative examples A1 to A5 shown in Table 13, and the microcrystalline glass and the chemically-strengthened microcrystalline glass in Comparative examples A1 to A5 were respectively prepared by referring to a preparation method of Embodiment A1.

The glass compositions of Embodiment A8 and Embodiment A14 were used to implement steps (1)-(3) of the preparation method in Embodiment A1, so as to prepare the microcrystalline glass, and specific process parameters during preparation were referred to Table 14.

The glass compositions of Embodiment A8 and Embodiment A14 were used to implement steps (1)-(4) of the preparation method in Embodiment A1, so as to prepare the chemically-strengthened microcrystalline glass, and specific process parameters of step (4) during preparation were referred to Table 15, and the rest of steps (1)-(3) remained the same as Embodiment A1.

### Test Example

Test methods and test devices were as follows.

An X-ray diffraction analyzer was used to perform a main crystalline phase test.

A scanning electron microscope was used to perform crystal appearance observation.

A Datacolor650 ultrahigh-precision desktop spectrophotometer colorimeter was used to perform a color b value test.

A spectrophotometer was used to perform a visible light transmittance test by referring to Standard ISO13468-1:1996.

The haze of glass was tested through an ASTMD1003-92 test.

The fracture toughness KIC of the glass was determined by referring to ASTME-1820, in MPa·m^{1/2}.

Machine sandpaper drop performance was measured by a controlled drop testing machine for mobile phones, and specific test conditions included: 180-mesh sandpaper, a total weight of 195 g, a basic height of 60 cm, 5 cm increments, once per height, until crushed.

According to the test methods and test devices in the test example, the properties of the microcrystalline glass and the chemically-strengthened microcrystalline glass obtained in Embodiments B1 to B14, the microcrystalline glass and the chemically-strengthened microcrystalline glass obtained in Comparative examples A1 to A5, the microcrystalline glass obtained according to the process parameters in Table 14, or the chemically-strengthened microcrystalline glass obtained according to the process parameters in Table 15 were respectively tested, and filled in the corresponding tables.

It is to be understood that, the test methods and test devices were common ways for evaluating related properties of the glass in the art, are only a means to represent or evaluate the technical solutions and technical effects of the present disclosure, and other test methods and test devices might be used as well, without affecting final results.

TABLE I1
Glass composition components and glass performance in Embodiments A1 to A7

| | | Embodi- | Embodi- | Embodi- | Embodi- | Embodi- | Embodi- | Embodi- |
|---|---|---|---|---|---|---|---|---|
| | | ment A1 | ment A2 | ment A3 | ment A4 | ment A5 | ment A6 | ment A7 |
| SiO₂ | | 72 | 72.3 | 72.5 | 72.7 | 72.8 | 73 | 73.2 |
| Al₂O₃ | | 7 | 7.1 | 7.2 | 7.3 | 7.4 | 7.5 | 7.5 |
| P₂O₅ | | 3 | 2.9 | 2.8 | 2.7 | 2.6 | 2.5 | 2.4 |
| Li₂O | | 12.5 | 12.3 | 12.2 | 12 | 11.7 | 11.5 | 11.5 |
| Na₂O | | 2 | 1.8 | 1.6 | 1.5 | 1.4 | 1.4 | 1.3 |
| ZrO₂ | | 3.5 | 3.6 | 3.7 | 3.8 | 3.9 | 4.1 | 4.1 |
| A | | 5 | 5.1 | 4.9 | 4.9 | 5 | 5 | 5.2 |
| B | | 0.85 | 0.80 | 0.77 | 0.72 | 0.66 | 0.61 | 0.62 |
| C₁ | | 1.17 | 1.24 | 1.32 | 1.41 | 1.50 | 1.64 | 1.71 |
| D | | 2.50 | 2.83 | 3.06 | 3.27 | 3.57 | 3.57 | 4.00 |
| Microcrys- | Li₂Si₂O₅/% | 38 | 37 | 36 | 35 | 35 | 36 | 36 |
| talline glass | LiAlSi₄O₁₀/% | 36 | 36 | 35 | 34 | 34 | 35 | 36 |
| | E | 1.06 | 1.03 | 1.03 | 1.03 | 1.03 | 1.03 | 1.00 |
| | Crystal | 70 | 68 | 70 | 71 | 68 | 70 | 72 |
| | size nm | | | | | | | |
| | Total | 74 | 73 | 71 | 69 | 69 | 71 | 72 |
| | crystalline | | | | | | | |
| | phase | | | | | | | |
| | content | | | | | | | |
| | b value | 0.35 | 0.34 | 0.33 | 0.33 | 0.33 | 0.33 | 0.32 |
| | Haze % | 0.14 | 0.13 | 0.13 | 0.13 | 0.13 | 0.12 | 0.12 |
| | Transmit- | 91.3 | 91.3 | 91.4 | 91.5 | 91.5 | 91.6 | 91.6 |
| | tance % of | | | | | | | |
| | 0.7 mm | | | | | | | |
| | microcrys- | | | | | | | |
| | talline | | | | | | | |
| | glass at | | | | | | | |
| | 560 nm | | | | | | | |

| | | | | | | | |
|---|---|---|---|---|---|---|---|
| M | 11.56 | 11.53 | 11.49 | 11.65 | 11.92 | 12.09 | 12.29 |
| Fracture toughness | 1.44 | 1.42 | 1.39 | 1.49 | 1.61 | 1.67 | 1.72 |
| KIC MPa · m^{1/2} | | | | | | | |
| 180-mesh sandpaper | 230 | 230 | 225 | 235 | 245 | 250 | 260 |
| drop height/cm | | | | | | | |

TABLE I2
Glass composition components and glass performance in Embodiments A8 to A14

| | | Embodi- | Embodi- | Embodi- | Embodi- | Embodi- | Embodi- | Embodi- |
|---|---|---|---|---|---|---|---|---|
| | | ment A8 | ment A9 | ment A10 | ment A11 | ment A12 | ment A13 | ment A14 |
| SiO₂ | | 73.4 | 73.6 | 73.8 | 73.9 | 74 | 74.2 | 74.3 |
| Al₂O₃ | | 7.6 | 7.8 | 7.9 | 8 | 8.2 | 8.4 | 8.5 |
| P₂O₅ | | 2.3 | 2.2 | 2.1 | 2.1 | 2 | 1.9 | 1.8 |
| Li₂O | | 11.3 | 11 | 10.9 | 10.7 | 10.6 | 10.3 | 10.2 |
| Na₂O | | 1.2 | 1.1 | 1 | 0.9 | 0.7 | 0.6 | 0.5 |
| ZrO₂ | | 4.2 | 4.3 | 4.3 | 4.4 | 4.5 | 4.6 | 4.7 |
| A | | 5.2 | 4.8 | 4.6 | 4.5 | 3.6 | 3.2 | 2.9 |
| B | | 0.57 | 0.49 | 0.47 | 0.42 | 0.37 | 0.29 | 0.26 |
| C₁ | | 1.83 | 1.95 | 2.05 | 2.10 | 2.25 | 2.42 | 2.61 |
| D | | 4.33 | 4.36 | 4.60 | 5.00 | 5.14 | 5.33 | 5.80 |
| Microcrys- | Li₂Si₂O₅/% | 36 | 36 | 35 | 35 | 35 | 33 | 32 |
| talline glass | LiAlSi₄O₁₀/% | 36 | 36 | 36 | 36 | 36 | 35 | 35 |
| | E | 1.00 | 1.00 | 0.97 | 0.97 | 0.97 | 0.94 | 0.91 |
| | Crystal | 70 | 68 | 70 | 72 | 72 | 70 | 77 |
| | size nm | | | | | | | |
| | Total | 72 | 72 | 71 | 71 | 71 | 68 | 67 |
| | crystalline | | | | | | | |
| | phase | | | | | | | |
| | content | | | | | | | |
| | b value | 0.32 | 0.32 | 0.33 | 0.33 | 0.34 | 0.35 | 0.36 |
| | Haze % | 0.11 | 0.12 | 0.12 | 0.13 | 0.13 | 0.14 | 0.15 |
| | Transmit- | 91.7 | 91.6 | 91.6 | 91.5 | 91.4 | 91.3 | 91.3 |
| | tance % of | | | | | | | |
| | 0.7 mm | | | | | | | |
| | microcrys- | | | | | | | |
| | talline | | | | | | | |
| | glass at | | | | | | | |
| | 560 nm | | | | | | | |

| | | | | | | | |
|---|---|---|---|---|---|---|---|
| M | 12.54 | 12.20 | 11.86 | 11.85 | 11.14 | 10.62 | 10.44 |
| Fracture toughness | 1.78 | 1.69 | 1.54 | 1.54 | 1.36 | 1.21 | 1.12 |
| KIC MPa · m^{1/2} | | | | | | | |
| 180-mesh sandpaper | 275 | 255 | 240 | 240 | 215 | 205 | 200 |
| drop height/cm | | | | | | | |

TABLE I3
Glass composition components and glass performance in Comparative examples A1 to A5

| | | Comparative | Comparative | Comparative | Comparative | Comparative |
|---|---|---|---|---|---|---|
| | | example A1 | example A2 | example A3 | example A4 | example A5 |
| SiO₂ | | 71.5 | 73 | 72.7 | 73.1 | 72.5 |
| Al₂O₃ | | 8 | 7 | 8.3 | 8 | 8 |
| P₂O₅ | | 3 | 3 | 3.4 | 1.7 | 3.8 |
| Li₂O | | 11.5 | 11.5 | 10 | 11.5 | 10.9 |
| Na₂O | | 1.2 | 1.2 | 0.7 | 0.9 | 1.1 |
| ZrO₂ | | 4.8 | 4.3 | 4.9 | 4.8 | 3.7 |
| A | | 0.5 | 8 | 2.9 | 2.1 | 2.7 |
| B | | 0.45 | 0.62 | 0.20 | 0.54 | 0.39 |
| C₁ | | 1.60 | 1.43 | 1.44 | 2.82 | 0.97 |
| D | | 0.42 | 6.67 | 4.14 | 2.33 | 2.45 |
| Microcrys- | Li₂Si₂O₅/% | 37 | 18 | 26 | 21 | 39 |
| talline glass | LiAlSi₄O₁₀/% | 29 | 30 | 35 | 38 | 23 |
| | E | 1.28 | 0.60 | 0.74 | 0.55 | 1.70 |
| | Crystal | 129 | 65 | 143 | 136 | 126 |
| | size nm | | | | | |
| | Total | 66 | 48 | 61 | 59 | 62 |
| | crystalline | | | | | |
| | phase | | | | | |
| | content | | | | | |
| | b value | 0.92 | 0.41 | 1.75 | 0.57 | 0.62 |
| | Haze % | 0.38 | 0.13 | 0.66 | 0.25 | 0.31 |
| | Transmit- | 88.9 | 91.3 | 87.7 | 89.9 | 89.5 |
| | tance % of | | | | | |
| | 0.7 mm | | | | | |
| | microcrys- | | | | | |
| | talline | | | | | |
| | glass at | | | | | |
| | 560 nm | | | | | |

| | | | | | |
|---|---|---|---|---|---|
| Fracture toughness | 0.72 | 0.43 | 0.71 | 0.68 | 0.64 |
| KIC MPa · m^{1/2} | | | | | |
| 180-mesh sandpaper | 165 | 130 | 165 | 160 | 155 |
| drop height/cm | | | | | |

TABLE I4
Process parameter and performance of microcrystalline glass
prepared by glass composition in Embodiments A8 to A14

| | | Glass composition of | | | Glass composition of | | |
|---|---|---|---|---|---|---|---|
| | | Embodiment A8 | | | Embodiment A14 | | |
| Treatment | Nucleation | 20 min, | 60 min, | 40 min, | 20 min, | 40 min, | 60 min, |
| system | treatment | 530° C., | 530° C., | 570° C., | 530° C., | 530o° C., | 570° C., |
| | | 3 h | 6 h | 8 h | 3 h | 6 h | 8 h |
| | Crystallization | 30 min, | 5 min, | 16 min, | 30 min, | 5 min, | 15 min, |
| | treatment | 680° C., | 680° C., | 720° C., | 680° C., | 680° C., | 720° C., |
| | | 3 h | 8 h | 8 h | 3 h | 8 h | 8 h |
| Crystalline | Li₂Si₂O₅/% | 36 | 46 | 47 | 32 | 41 | 44 |
| phase | LiAlSi₄O₁₀/% | 36 | 46 | 47 | 35 | 43 | 45 |
| | E | 1.00 | 1.00 | 1.00 | 0.91 | 0.95 | 0.98 |

| | | | | | | |
|---|---|---|---|---|---|---|
| Crystal | 70 | 83 | 90 | 77 | 87 | 93 |
| size nm | | | | | | |
| Total crystalline | 72 | 92 | 94 | 67 | 84 | 89 |
| phase content | | | | | | |
| b value after | 0.32 | 0.33 | 0.34 | 0.36 | 0.37 | 0.39 |
| heat treatment | | | | | | |
| Haze % | 0.11 | 0.12 | 0.13 | 0.15 | 0.16 | 0.17 |
| Transmittance | 91.7 | 91.6 | 91.5 | 91.3 | 91.2 | 91 |
| % of 0.7 mm | | | | | | |
| microcrystalline | | | | | | |
| glass at 560 nm | | | | | | |

The time for the nucleation treatment and crystallization treatment represented the time for heating, the temperature represented a target heating temperature, and the time represented a treatment time.

TABLE I5
Process parameter and performance of the chemically-strengthened microcrystalline
glass prepared by glass composition in Embodiments A8 to A14
Glass composition of Embodiment A8

| | | | | | | | | | |
|---|---|---|---|---|---|---|---|---|---|
| Chemical | Molten | NaNO₃ | NaNO₃ | NaNO₃ | NaNO₃ | NaNO₃ | NaNO₃ | NaNO₃ | NaNO₃ |
| strength- | salt | 40%, | 40%, | 40%, | 40%, | 20%, | 20%, | 20%, | 20%, |
| ening | concen- | KNO₃6 | KNO₃6 | KNO₃6 | KNO₃6 | KNO₃8 | KNO₃8 | KNO₃8 | KNO₃8 |
| system | tration | 0% | 0% | 0% | 0% | 0% | 0% | 0% | 0% |
| | Strength- | 420° C., | 420° C., | 500° C., | 500° C., | 420° C., | 420° C., | 500° C., | 500° C., |
| | ening | 3 h | 8 h | 3 h | 8 h | 3 h | 8 h | 3 h | 8 h |
| | temperature, | | | | | | | | |
| | time | | | | | | | | |

| | | | | | | | | |
|---|---|---|---|---|---|---|---|---|
| 180-mesh sandpaper | 275 | 295 | 290 | 300 | 280 | 300 | 295 | 300 |
| drop height/cm | | | | | | | | |

Glass composition of Embodiment A14

| | | | | | | | | | |
|---|---|---|---|---|---|---|---|---|---|
| Chemical | Molten | NaNO₃ | NaNO₃ | NaNO₃ | NaNO₃ | NaNO₃ | NaNO₃ | NaNO₃ | NaNO₃ |
| strength- | salt | 40%, | 40%, | 40%, | 40%, | 20%, | 20%, | 20%, | 20%, |
| ening | concen- | KNO₃6 | KNO₃6 | KNO₃6 | KNO₃6 | KNO₃8 | KNO₃8 | KNO₃8 | KNO₃8 |
| system | tration | 0% | 0% | 0% | 0% | 0% | 0% | 0% | 0% |
| | Strength- | 420° C., | 420° C., | 500° C., | 500° C., | 420° C., | 420° C., | 500° C., | 500° C., |
| | ening | 3 h | 8 h | 3 h | 8 h | 3 h | 8 h | 3 h | 8 h |
| | temperature, | | | | | | | | |
| | time | | | | | | | | |

| | | | | | | | | |
|---|---|---|---|---|---|---|---|---|
| 180-mesh sandpaper | 200 | 220 | 205 | 230 | 205 | 225 | 210 | 230 |
| drop height/cm | | | | | | | | |

From performance test results of the microcrystalline glass of various embodiments shown in Table I1, Table I2, Table I4, and Table I5, it might be seen that, by using the Embodiments A1-A14 of the technical solutions of the present disclosure, the crystalline phase lithium disilicate Li₂Si₂O₅ in the microcrystalline glass obtained after heat treatment was greater than 30%, the crystalline phase petalite LiAlSi₄O₁₀ was greater than 30%, and the total crystalline phase in the microcrystalline glass was greater than 68%. The transmittance of the microcrystalline glass with 0.7 mm was greater than 91%, the haze was less than 0.17, and the b value was less than 0.4. An average crystal size of the crystal particles of the microcrystalline glass was less than 100 nm. The fracture toughness KIC of the microcrystalline glass was greater than 1.1 MPa·m^{1/2}, and a drop resistance height was greater than 200 cm.

From Table 13, it might be seen that, in Comparative example A1, SiO_{2=71.5}%, A=0.5, and D=0.42, failing to meet requirements of the glass composition of the present disclosure, in the heat-treated microcrystalline glass, Li₂Si₂O₅/LiAISi₄O_{10=0.81}, crystal size >100 nm; the transmittance was low, the b value was too large, the haze was large; and the chemically-strengthened mechanical property was relatively poor.

In Comparative example A2, A=8, and D=6.67, failing to meet requirements of the glass composition of the present disclosure, the microcrystalline phase content in the heat-treated microcrystalline glass was less, Li₂Si₂O₅/LiAISi₄O_{10=0.6}, and the chemically-strengthened mechanical property was relatively poor.

In Comparative example A3, Li₂O=10%, and B=0.2, failing to meet requirements of the glass composition of the present disclosure, the microcrystalline phase content in the heat-treated microcrystalline glass was less, Li₂Si₂O₅/LiAISi₄O_{10=0.74}, crystal size >100 nm; the transmittance was low, the b value was too large, the haze was large; and the chemically-strengthened mechanical property was relatively poor.

In Comparative example A4, P₂O₅=1.7%, A=2.1, C1=2.82, and D=2.33, failing to meet requirements of the glass composition of the present disclosure, the microcrystalline phase content in the heat-treated microcrystalline glass was less, Li₂Si₂O₅/LiAISi₄O_{10=0.55}, crystal size >100 nm; the transmittance was low, the b value was too large, the haze was large; and the chemically-strengthened mechanical property was relatively poor.

In Comparative example A5, P₂O₅=3.8%, A=2.7, C1=0.97, and D=2.45, failing to meet requirements of the glass composition of the present disclosure, the microcrystalline phase content in the heat-treated microcrystalline glass was less, Li₂Si₂O₅/LiAlSi₄O₁₀=1.7, crystal size >100 nm; the transmittance was low, the b value was too large, the haze was large; and the chemically-strengthened mechanical property was relatively poor.

Compared to the fracture toughness KIC value (0.43-0.72 MPa·m^{1/2}) of the chemically-strengthened microcrystalline glass in the comparative examples, the fracture toughness KIC value (1.012-1.78 MPa·m^{1/2}) of the chemically-strengthened microcrystalline glass in the embodiments of the present disclosure was higher, it indicated that the situations of a reduced crystal content and a damaged interlocking structure of two crystalline phases occurred in the microcrystalline glass in the embodiments of the present disclosure during the chemical strengthening process were significantly improved. Compared to the high b value and high haze of the microcrystalline glass in the comparative examples, the b value and haze of the microcrystalline glass in the embodiments of the present disclosure were significantly lower, it indicated that the reduction of the b value and haze of the microcrystalline glass in the embodiments of the present disclosure was realized. Finally, the strengthening performance of the obtained the chemically-strengthened microcrystalline glass was excellent.

### Embodiment

(1) A glass composition was weighed, and included, by mass percentage, 71.5% of SiO₂, 8.7% of Al₂O₃, 3% of P₂O₅, 0.1% of B2O₃, 10.2% of Li₂O, 1.5% of Na₂O, and 5% of ZrO₂, A=−1.1, B=0.19, and C₂=1.57.
(2) The glass composition was mixed, melted, clarified, homogenized, molded, annealed and finally cut to obtain a basic glass.
(3) The basic glass was heated from the room temperature to 510° C. in 20 min, the first nucleation treatment was performed, and the time for the first nucleation treatment was 3 h; a temperature was heated to 580° C. in 5 min, the second nucleation treatment was performed, and the time for the second nucleation treatment was 3 h; the temperature was heated to 650° C. in 30 min, crystallization treatment was performed, and the time for the crystallization treatment was 3 h; and the temperature was cooled to the room temperature to obtain a microcrystalline glass.
(4) The microcrystalline glass was pre-treated, and then placed into an ion exchange bath for a salt bath, so as to obtain the chemically-strengthened microcrystalline glass, the ion exchange bath included, by mass percentage, 20% of NaNO₃ and 80% of KNO₃, a strengthening temperature of the salt bath was 420° C., and a strengthening time of the salt bath was 3 h.

Raw materials were weighed according to component proportions of the glass composition of various embodiments shown in Table II1 and Table II2, and microcrystalline glass and the chemically-strengthened microcrystalline glass in other Embodiment B2 to Embodiment B15 were respectively prepared by referring to a preparation method of Embodiment B1.

Raw materials were weighed according to component proportions of the glass composition of Comparative examples B1 to B7 shown in Table II3, and microcrystalline glass and the chemically-strengthened microcrystalline glass in Comparative examples B1 to B7 were respectively prepared by referring to a preparation method of Embodiment B1.

The glass compositions of Embodiments B1 and B9 were used to implement steps (1)-(3) of the preparation method in Embodiment B1, so as to prepare the microcrystalline glass, and specific process parameters during preparation were referred to Table 114.

### Test Example

Test methods and test devices were as follows.

An X-ray diffraction analyzer was used to perform a main crystalline phase test.

A scanning electron microscope was used to perform crystal appearance observation.

A Datacolor650 ultrahigh-precision desktop spectrophotometer colorimeter was used to perform a color b value test.

A spectrophotometer was used to perform a visible light transmittance test by referring to Standard ISO13468-1:1996.

The haze of glass was tested through an ASTMD1003-92 test.

Machine sandpaper drop performance was measured by a controlled drop testing machine for mobile phones, and specific test conditions included: 180-mesh sandpaper, a total weight of 195 g, a basic height of 60 cm, 5 cm increments, once per height, until crushed.

According to the test methods and test devices in the test example, the properties of the microcrystalline glass and the chemically-strengthened microcrystalline glass obtained in Embodiments B1 to B15, the microcrystalline glass and the chemically-strengthened microcrystalline glass obtained in Comparative examples B1 to B7, or the microcrystalline glass obtained according to the process parameters in Table II4 were respectively tested, and filled in the corresponding tables.

It is to be understood that, the test methods and test devices were common ways for evaluating related properties of the glass in the art, are only a means to represent or evaluate the technical solutions and technical effects of the present disclosure, and other test methods and test devices might be used as well, without affecting final results.

TABLE II1
Glass composition components and glass performance in Embodiments B1 to B8

| | | Embodi- | Embodi- | Embodi- | Embodi- | Embodi- | Embodi- | Embodi- | Embodi- |
|---|---|---|---|---|---|---|---|---|---|
| | | ment B1 | ment B2 | ment B3 | ment B4 | ment B5 | ment B6 | ment B7 | ment B8 |
| SiO₂ | | 71.5 | 71.7 | 72 | 72.1 | 72.3 | 72.5 | 72.8 | 73 |
| Al₂O₃ | | 8.7 | 8.6 | 8.4 | 8.4 | 8.1 | 8 | 7.9 | 7.8 |
| P₂O₅ | | 3 | 2.9 | 2.8 | 2.7 | 2.6 | 2.5 | 2.5 | 2.4 |
| B₂O₃ | | 0.1 | 0.2 | 0.3 | 0.3 | 0.5 | 0.5 | 0.6 | 0.6 |
| Li₂O | | 10.2 | 10.3 | 10.5 | 10.6 | 10.8 | 11 | 11 | 11.2 |
| Na₂O | | 1.5 | 1.4 | 1.3 | 1.2 | 1.1 | 1.1 | 1 | 0.9 |
| ZrO₂ | | 5 | 4.9 | 4.7 | 4.7 | 4.6 | 4.4 | 4.2 | 4.1 |
| A | | −1.1 | −0.5 | 0.6 | 0.5 | 2.1 | 2.5 | 3.4 | 3.8 |
| B | | 0.19 | 0.22 | 0.28 | 0.30 | 0.38 | 0.43 | 0.46 | 0.52 |
| C₂ | | 1.57 | 1.48 | 1.36 | 1.41 | 1.19 | 1.16 | 0.96 | 0.96 |
| Microcrys- | Li₂Si₂O₅/% | 30 | 32 | 33 | 35 | 37 | 38 | 37 | 38 |
| talline glass | LiAlSi₄O₁₀/% | 33 | 34 | 35 | 35 | 36 | 37 | 37 | 37 |
| | Crystal | 77 | 75 | 72 | 70 | 72 | 70 | 72 | 70 |
| | size nm | | | | | | | | |
| | Total | 63 | 66 | 68 | 70 | 73 | 75 | 74 | 75 |
| | crystalline | | | | | | | | |
| | phase | | | | | | | | |
| | content | | | | | | | | |
| | b value | 0.37 | 0.36 | 0.35 | 0.34 | 0.34 | 0.33 | 0.32 | 0.32 |
| | Haze % | 0.14 | 0.14 | 0.13 | 0.13 | 0.12 | 0.12 | 0.11 | 0.11 |
| | Transmit- | 91.3 | 91.3 | 91.4 | 91.4 | 91.5 | 91.5 | 91.6 | 91.6 |
| | tance % of | | | | | | | | |
| | 0.7 mm | | | | | | | | |
| | microcrys- | | | | | | | | |
| | talline | | | | | | | | |
| | glass at | | | | | | | | |
| | 560 nm | | | | | | | | |

| | | | | | | | | |
|---|---|---|---|---|---|---|---|---|
| 180-mesh sandpaper | 200 | 210 | 215 | 220 | 220 | 225 | 230 | 235 |
| drop height/cm | | | | | | | | |

TABLE II2
Glass composition components and glass performance in Embodiments B9 to B15

| | | Embodi- | Embodi- | Embodi- | Embodi- | Embodi- | Embodi- | Embodi- |
|---|---|---|---|---|---|---|---|---|
| | | ment B9 | ment B10 | ment B11 | ment B12 | ment B13 | ment B14 | ment B15 |
| SiO₂ | | 73.1 | 73.4 | 73.5 | 73.8 | 74 | 74.2 | 74.5 |
| Al₂O₃ | | 7.8 | 7.7 | 7.7 | 7.6 | 7.5 | 7.4 | 7.3 |
| P₂O₅ | | 2.3 | 2.2 | 2.1 | 2.1 | 2 | 1.9 | 1.7 |
| B₂O₃ | | 0.7 | 0.7 | 0.7 | 0.7 | 0.8 | 0.9 | 1 |
| Li₂O | | 11.3 | 11.4 | 11.5 | 11.6 | 11.8 | 11.9 | 12 |
| Na₂O | | 0.8 | 0.7 | 0.7 | 0.6 | 0.5 | 0.5 | 0.4 |
| ZrO₂ | | 4 | 3.9 | 3.8 | 3.6 | 3.4 | 3.2 | 3.1 |
| A | | 3.7 | 4.4 | 4.3 | 5 | 5.4 | 6 | 6.7 |
| B | | 0.56 | 0.61 | 0.64 | 0.70 | 0.80 | 0.88 | 0.98 |
| C₂ | | 0.83 | 0.82 | 0.81 | 0.71 | 0.50 | 0.26 | 0.06 |
| Microcrys- | Li₂Si₂O₅/% | 39 | 37 | 37 | 36 | 35 | 35 | 33 |
| talline glass | LiAlSi₄O₁₀/% | 38 | 35 | 34 | 34 | 34 | 33 | 32 |
| | Crystal | 70 | 72 | 70 | 68 | 69 | 66 | 65 |
| | size nm | | | | | | | |
| | Total | 77 | 72 | 71 | 70 | 69 | 68 | 65 |
| | crystalline | | | | | | | |
| | phase | | | | | | | |
| | content | | | | | | | |
| | b value | 0.31 | 0.31 | 0.32 | 0.33 | 0.34 | 0.34 | 0.35 |
| | Haze % | 0.1 | 0.11 | 0.12 | 0.12 | 0.13 | 0.13 | 0.14 |
| | Transmit- | 91.7 | 91.6 | 91.6 | 91.5 | 91.4 | 91.3 | 91.3 |
| | tance % of | | | | | | | |
| | 0.7 mm | | | | | | | |
| | microcrys- | | | | | | | |
| | talline | | | | | | | |
| | glass at | | | | | | | |
| | 560 nm | | | | | | | |

| | | | | | | | |
|---|---|---|---|---|---|---|---|
| 180-mesh sandpaper | 240 | 230 | 225 | 220 | 215 | 210 | 205 |
| drop height/cm | | | | | | | |

TABLE II3
Glass composition components and glass performance in Comparative examples B1 to B7

| | | Comparative | Comparative | Comparative | Comparative | Comparative | Comparative | Comparative |
|---|---|---|---|---|---|---|---|---|
| | | example B1 | example B2 | example B3 | example B4 | example B5 | example B6 | example B7 |
| SiO₂ | | 73.2 | 73.5 | 72.2 | 74.7 | 73.2 | 72.2 | 72.2 |
| Al₂O₃ | | 8 | 7.9 | 9.5 | 7.1 | 7.5 | 9 | 7.8 |
| P₂O₅ | | 2.4 | 2.3 | 2.8 | 2.8 | 2.4 | 3.4 | 2.2 |
| B₂O₃ | | 0 | 1.1 | 0.4 | 0.8 | 0.4 | 0.6 | 0.2 |
| Li₂O | | 11.6 | 11.2 | 10 | 10 | 13 | 8.5 | 11.9 |
| Na₂O | | 1 | 1.2 | 1.4 | 0.9 | 0.8 | 1.8 | 0.9 |
| ZrO₂ | | 3.8 | 2.8 | 3.7 | 3.7 | 2.7 | 4.5 | 4.8 |
| A | | 2 | 3.7 | −4.8 | 12.1 | 2.2 | 1.2 | 1.6 |
| B | | 0.58 | 0.65 | 0.08 | 0.45 | 1.08 | −0.06 | 0.59 |
| C₂ | | 1.58 | −0.22 | 0.89 | 0.46 | 0.63 | 0.79 | 1.91 |
| Microcrys- | Li₂Si₂O₅/% | 32 | 38 | 8 | 13 | 35 | 6 | 32 |
| talline glass | LiAlSi₄O₁₀/% | 37 | 30 | 37 | 18 | 37 | 25 | 39 |
| | Crystal | 159 | 155 | 195 | 65 | 143 | 66 | 122 |
| | size nm | | | | | | | |
| | Total | 69 | 68 | 45 | 31 | 72 | 31 | 71 |
| | crystalline | | | | | | | |
| | phase | | | | | | | |
| | content | | | | | | | |
| | b value | 1.92 | 1.56 | 2.28 | 0.45 | 3.45 | 0.42 | 1.23 |
| | Haze % | 0.53 | 0.43 | 0.87 | 0.12 | 0.86 | 0.11 | 0.31 |
| | Transmit- | 87.1 | 87.4 | 85.2 | 91.3 | 85.7 | 91.2 | 88.3 |
| | tance % of | | | | | | | |
| | 0.7 mm | | | | | | | |
| | microcrys- | | | | | | | |
| | talline | | | | | | | |
| | glass at | | | | | | | |
| | 560 nm | | | | | | | |

| | | | | | | | |
|---|---|---|---|---|---|---|---|
| 180-mesh sandpaper | 210 | 190 | 150 | 105 | 220 | 100 | 220 |
| drop height/cm | | | | | | | |

TABLE II4
Process parameter and performance of microcrystalline glass
prepared by glass composition in Embodiments B1 and B9

| | | Glass composition of | | | | Glass composition of | | | |
|---|---|---|---|---|---|---|---|---|---|
| | | Embodiment B1 | | | | Embodiment B9 | | | |
| Treatment | First | 20 min, | 60 min, | 40 min, | 40 min, | 20 min, | 40 min, | 60 min, | 40 min, |
| system | nucleation | 510° C., | 510° C., | 540° C., | 540° C., | 510° C., | 510° C., | 540° C., | 540° C., |
| | treatment | 3 h | 8 h | 3 h | 8 h | 3 h | 8 h | 3 h | 8 h |
| | Second | 5 min, | 30 min, | 17 min, | 16 min, | 5 min, | 17 min, | 5 min, | 30 min, |
| | nucleation | 580° C., | 580° C., | 610° C., | 610° C., | 580° C., | 580° C., | 610° C., | 610° C., |
| | treatment | 3 h | 8 h | 3 h | 8 h | 3 h | 8 h | 3 h | 8 h |
| | Crystallization | 30 min, | 5 min, | 16 min, | 17 min, | 30 min, | 5 min, | 15 min, | 16 min, |
| | treatment | 650° C., | 650° C., | 680° C., | 680° C., | 650° C., | 650° C., | 680° C., | 680° C., |
| | | 3 h | 8 h | 3 h | 8 h | 3 h | 8 h | 3 h | 8 h |
| Crystalline | Li₂Si₂O₅/% | 30 | 37 | 36 | 41 | 39 | 43 | 42 | 45 |
| phase | LiAlSi₄O₁₀/% | 33 | 40 | 38 | 45 | 38 | 41 | 40 | 43 |

| | | | | | | | | |
|---|---|---|---|---|---|---|---|---|
| Crystal | 77 | 85 | 86 | 96 | 70 | 80 | 82 | 89 |
| size nm | | | | | | | | |
| Total crystalline | 63 | 77 | 74 | 86 | 77 | 84 | 82 | 88 |
| phase content | | | | | | | | |
| b value after | 0.37 | 0.38 | 0.39 | 0.4 | 0.31 | 0.32 | 0.33 | 0.35 |
| heat treatment | | | | | | | | |
| Haze % | 0.14 | 0.16 | 0.15 | 0.17 | 0.1 | 0.13 | 0.12 | 0.14 |
| Transmittance | 91.3 | 91.2 | 91.3 | 91.1 | 91.7 | 91.6 | 91.7 | 91.5 |
| % of 0.7 mm | | | | | | | | |
| microcrystalline | | | | | | | | |
| glass at 560 nm | | | | | | | | |

The time for the first nucleation treatment, the second nucleation treatment, and crystallization treatment represented the time for heating, the temperature represented a target heating temperature, and the time represented a treatment time.

From performance test results of the microcrystalline glass of various embodiments shown in Table II1, Table II2, and Table II4, it might be seen that, by using the Embodiments B1-B15 of the technical solutions of the present disclosure, the lithium disilicate Li₂Si₂O₅ in the microcrystalline glass accounted for 30%-45%, the petalite LiAISi₄O₁₀ accounted for 30%-45%, the total crystalline phase accounted for 60%-90% of the microcrystalline glass, crystal sizes were uniform, and an average crystal size was less than 100 nm. The transmittance of the 0.7 mm microcrystalline glass at a wavelength of 560 nm was greater than 91%, the haze was less than 0.17, the b value was less than 0.5, and the drop resistance height was greater than 200 cm.

From Table 113, it might be seen that, in Comparative example 1, B2O₃₌₀%, and C₂=1.58, failing to meet requirements of the glass composition of the present disclosure, the microcrystalline phase content in the heat-treated microcrystalline glass was less, crystal size >100 nm; the transmittance was low, the b value was too large, and the haze was large.

In Comparative example B2, B2O_{3=1.1}%, but C₂=−0.22, failing to meet requirements of the glass composition of the present disclosure, the microcrystalline phase content in the heat-treated microcrystalline glass was less, crystal size >100 nm; the transmittance was low, the b value was too large, the haze was large, and drop resistance was poor.

In Comparative example B3, Al₂O₃=9.5%, A=−4.8, and B=0.08, failing to meet requirements of the glass composition of the present disclosure, the microcrystalline phase content in the heat-treated microcrystalline glass was less, crystal size >100 nm; the transmittance was low, the b value was too large, the haze was large, and drop resistance was poor.

In Comparative example B4, SiO₂=74.7%, and A=12.1, failing to meet requirements of the glass composition of the present disclosure, the microcrystalline phase content in the heat-treated microcrystalline glass was less, and drop resistance was poor.

In Comparative example B5, Li₂O=13%, and B=1.08, failing to meet requirements of the glass composition of the present disclosure, the microcrystalline phase content in the heat-treated microcrystalline glass was less, crystal size >100 nm; the transmittance was low, the b value was too large, and the haze was large.

In Comparative example B6, Al₂O₃=9%, and B=−0.06, failing to meet requirements of the glass composition of the present disclosure, the microcrystalline phase content in the heat-treated microcrystalline glass was less, and drop resistance was poor.

In Comparative example B7, although the glass components were within the requirements of the present disclosure, C₂=1.91, failing to meet requirements of the glass composition of the present disclosure, the microcrystalline phase content in the heat-treated microcrystalline glass was less, crystal size >100 nm; the transmittance was low, the b value was too large, and the haze was large.

Compared to the b value and haze of the microcrystalline glass in the comparative examples, the b value of the microcrystalline glass in the embodiments of the present disclosure significantly reduced, the haze significantly reduced, it indicated that the problems of the relatively-large b value and relatively-high haze of existing prepared microcrystalline glass can be effectively solved in the embodiments of the present disclosure, and the strengthening performance of the obtained microcrystalline glass was excellent.

### Embodiment

(1) A glass composition was weighed, and included, by mass percentage, 71.5% of SiO₂, 6.2% of Al₂O₃, 1.7% of P₂O₅, 0.1% of B2O₃, 12% of Li₂O, 2% of Na₂O, 1.5% of CaO, and 5% of ZrO₂, A=10.3, B=0.87, and C₃=2.19.
(2) The glass composition was mixed, melted, clarified, homogenized, molded, annealed and finally cut to obtain a basic glass.
(3) The basic glass was heated from the room temperature to 510° C. in 20 min, a first nucleation treatment was performed, and the time for the first nucleation treatment was 3 h; the temperature was heated to 580° C. in 5 min, a second nucleation treatment was performed, and the time for the second nucleation treatment was 3 h; the temperature was heated to 650° C. in 30 min, a crystallization treatment was performed, and the time for the crystallization treatment was 3 h; and the temperature was cooled to the room temperature to obtain a microcrystalline glass.
(4) The microcrystalline glass was pre-treated, and then placed into an ion exchange bath for a salt bath, so as to obtain the chemically-strengthened microcrystalline glass, the ion exchange bath included, by mass percentage, 40% of NaNO₃ and 60% of KNO₃, a strengthening temperature of the salt bath was 500° C., and a strengthening time of the salt bath was 8 h.

Raw materials were weighed according to component proportions of the glass composition of various embodiments shown in Table III1 and Table III2, and microcrystalline glass and the chemically-strengthened microcrystalline glass in other Embodiment C2 to Embodiment C16 were respectively prepared by referring to a preparation method of Embodiment C1.

Raw materials were weighed according to component proportions of the glass composition of Comparative examples C1 to C6 shown in Table III3, and microcrystalline glass and the chemically-strengthened microcrystalline glass in Comparative examples C₁ to C₆ were respectively prepared by referring to a preparation method of Embodiment C1.

The glass compositions of Embodiments C1 and C8 were used to implement steps (1)-(3) of the preparation method in Embodiment C1, so as to prepare the microcrystalline glass, and specific process parameters during preparation were referred to Table III4.

The glass compositions of Embodiment C1 and C8 were used to implement steps (1)-(4) of the preparation method in Embodiment C1, so as to prepare the chemically-strengthened microcrystalline glass, and specific process parameters of step (4) during preparation were referred to Table III5, and the rest of steps (1)-(3) remained the same as Embodiment C₁.

### Test Example

Test methods and test devices were as follows.

An X-ray diffraction analyzer was used to perform a main crystalline phase test.

A scanning electron microscope was used to perform crystal appearance observation.

A Datacolor650 ultrahigh-precision desktop spectrophotometer colorimeter was used to perform a color b value test.

A spectrophotometer was used to perform a visible light transmittance test by referring to Standard ISO13468-1:1996.

The haze of glass was tested through an ASTMD1003-92 test.

Machine sandpaper drop performance was measured by a controlled drop testing machine for mobile phones, and specific test conditions included: 180-mesh sandpaper, a total weight of 195 g, a basic height of 60 cm, 5 cm increments, once per height, until crushed.

According to the test methods and test devices in the test example, the properties of the microcrystalline glass and the chemically-strengthened microcrystalline glass obtained in Embodiments C1 to C16, the microcrystalline glass and the chemically-strengthened microcrystalline glass obtained in Comparative examples C1 to C6, the microcrystalline glass obtained according to the process parameters in Table III4, or the chemically-strengthened microcrystalline glass obtained according to the process parameters in Table III5 were respectively tested, and filled in the corresponding tables.

It is to be understood that, the test methods and test devices were common ways for evaluating related properties of the glass in the art, are only a means to represent or evaluate the technical solutions and technical effects of the present disclosure, and other test methods and test devices might be used as well, without affecting final results.

TABLE III1
Glass composition components and glass performance in Embodiments C1 to C8

| | | Embodi- | Embodi- | Embodi- | Embodi- | Embodi- | Embodi- | Embodi- | Embodi- |
|---|---|---|---|---|---|---|---|---|---|
| | | ment C1 | ment C2 | ment C3 | ment C4 | ment C5 | ment C6 | ment C7 | ment C8 |
| SiO₂ | | 71.5 | 71.7 | 71.9 | 72 | 72.1 | 72.3 | 72.5 | 72.6 |
| Al₂O₃ | | 6.2 | 6.3 | 6.5 | 6.8 | 7 | 7.2 | 7.5 | 7.6 |
| P₂O₅ | | 1.7 | 1.8 | 1.9 | 2 | 2 | 2.1 | 2.2 | 2.2 |
| B₂O₃ | | 0.1 | 0.2 | 0.3 | 0.4 | 0.4 | 0.5 | 0.6 | 0.7 |
| Li₂O | | 12 | 11.9 | 11.8 | 11.7 | 11.7 | 11.7 | 11.6 | 11.5 |
| Na₂O | | 2 | 1.9 | 1.8 | 1.7 | 1.6 | 1.5 | 1.1 | 1 |
| CaO | | 1.5 | 1.4 | 1.3 | 1 | 0.9 | 0.7 | 0.6 | 0.6 |
| ZrO₂ | | 5 | 4.8 | 4.5 | 4.4 | 4.3 | 4 | 3.9 | 3.8 |
| A | | 10.3 | 10.1 | 9.3 | 7.8 | 6.7 | 5.7 | 4.3 | 4 |
| B | | 0.87 | 0.85 | 0.83 | 0.77 | 0.75 | 0.74 | 0.67 | 0.65 |
| C₃ | | 2.19 | 2.13 | 2.00 | 2.13 | 2.13 | 2.06 | 2.06 | 2.13 |
| Microcrys- | Li₂Si₂O₅/% | 32 | 32 | 33 | 35 | 36 | 38 | 37 | 38 |
| talline glass | LiAlSi₄O₁₀/% | 33 | 35 | 35 | 35 | 37 | 37 | 38 | 38 |
| | Crystal | 76 | 74 | 70 | 72 | 70 | 70 | 72 | 70 |
| | size nm | | | | | | | | |
| | Total | 65 | 67 | 68 | 70 | 73 | 75 | 75 | 76 |
| | crystalline | | | | | | | | |
| | phase | | | | | | | | |
| | content | | | | | | | | |
| | b value | 0.39 | 0.38 | 0.37 | 0.36 | 0.35 | 0.34 | 0.33 | 0.32 |
| | Transmit- | 91.2 | 91.3 | 91.4 | 91.4 | 91.5 | 91.6 | 91.6 | 91.7 |
| | tance % of | | | | | | | | |
| | 0.7 mm | | | | | | | | |
| | microcrys- | | | | | | | | |
| | talline | | | | | | | | |
| | glass at | | | | | | | | |
| | 560 nm | | | | | | | | |
| | Haze % | 0.16 | 0.15 | 0.14 | 0.13 | 0.13 | 0.13 | 0.12 | 0.1 |
| Chemically- | Li₂Si₂O₅/% | 30 | 30 | 31 | 32 | 33 | 35 | 34 | 36 |
| strengthened | LiAlSi₄O₁₀/% | 30 | 32 | 32 | 32 | 34 | 34 | 35 | 35 |
| microcrys- | Total | 60 | 62 | 63 | 64 | 67 | 69 | 69 | 71 |
| talline glass | crystalline | | | | | | | | |
| | phase | | | | | | | | |
| | content | | | | | | | | |

| | | | | | | | | |
|---|---|---|---|---|---|---|---|---|
| 180-mesh sandpaper | 200 | 215 | 215 | 220 | 220 | 225 | 230 | 235 |
| drop height/cm | | | | | | | | |

TABLE III2
Glass composition components and glass performance in Embodiments C9 to C16

| | | Embodi- | Embodi- | Embodi- | Embodi- | Embodi- | Embodi- | Embodi- | Embodi- |
|---|---|---|---|---|---|---|---|---|---|
| | | ment C9 | ment C10 | ment C11 | ment C12 | ment C13 | ment C14 | ment C15 | ment C16 |
| SiO₂ | | 72.7 | 72.8 | 73 | 73.2 | 73.5 | 73.6 | 73.7 | 74 |
| Al₂O₃ | | 7.7 | 7.9 | 8 | 8.1 | 8.2 | 8.3 | 8.4 | 8.5 |
| P₂O₅ | | 2.3 | 2.3 | 2.3 | 2.4 | 2.4 | 2.5 | 2.5 | 2.6 |
| B₂O₃ | | 0.8 | 0.8 | 0.9 | 1 | 1.1 | 1.2 | 1.4 | 1.7 |
| Li₂O | | 11.4 | 11.3 | 11.3 | 11 | 10.8 | 10.6 | 10.5 | 10 |
| Na₂O | | 0.9 | 0.8 | 0.6 | 0.5 | 0.4 | 0.3 | 0.2 | 0.1 |
| CaO | | 0.5 | 0.5 | 0.4 | 0.4 | 0.3 | 0.3 | 0.2 | 0.1 |
| ZrO₂ | | 3.7 | 3.6 | 3.5 | 3.4 | 3.3 | 3.2 | 3.1 | 3 |
| A | | 3.7 | 2.8 | 2.4 | 2.6 | 2.7 | 2.6 | 2.3 | 3 |
| B | | 0.62 | 0.58 | 0.57 | 0.50 | 0.46 | 0.40 | 0.38 | 0.27 |
| C₃ | | 2.13 | 2.07 | 2.21 | 2.14 | 2.31 | 2.23 | 2.64 | 3.22 |
| Microcrys- | Li₂Si₂O₅/% | 39 | 37 | 37 | 35 | 35 | 35 | 34 | 33 |
| talline glass | LiAlSi₄O₁₀/% | 37 | 36 | 35 | 35 | 34 | 33 | 33 | 32 |
| | Crystal | 72 | 72 | 70 | 68 | 70 | 74 | 70 | 72 |
| | size nm | | | | | | | | |
| | Total | 76 | 73 | 72 | 70 | 69 | 68 | 67 | 65 |
| | crystalline | | | | | | | | |
| | phase | | | | | | | | |
| | content | | | | | | | | |
| | b value | 0.33 | 0.34 | 0.34 | 0.35 | 0.36 | 0.37 | 0.37 | 0.38 |
| | Transmit- | 91.6 | 91.6 | 91.5 | 91.5 | 91.4 | 91.4 | 91.3 | 91.3 |
| | tance % of | | | | | | | | |
| | 0.7 mm | | | | | | | | |
| | microcrys- | | | | | | | | |
| | talline | | | | | | | | |
| | glass at | | | | | | | | |
| | 560 nm | | | | | | | | |
| | Haze % | 0.11 | 0.11 | 0.12 | 0.13 | 0.13 | 0.14 | 0.15 | 0.15 |
| Chemically- | Li₂Si₂O₅/% | 36 | 34 | 34 | 32 | 32 | 31 | 31 | 30 |
| strengthened | LiAlSi₄O₁₀/% | 34 | 33 | 32 | 32 | 32 | 31 | 30 | 30 |
| microcrys- | Total | 70 | 67 | 66 | 64 | 64 | 62 | 61 | 60 |
| talline glass | crystalline | | | | | | | | |
| | phase | | | | | | | | |
| | content | | | | | | | | |

| | | | | | | | | |
|---|---|---|---|---|---|---|---|---|
| 180-mesh sandpaper | 230 | 225 | 220 | 220 | 220 | 210 | 205 | 200 |
| drop height/cm | | | | | | | | |

TABLE III3
Glass composition components and glass performance in Comparative examples C1 to C6

| | | Comparative | Comparative | Comparative | Comparative | Comparative | Comparative |
|---|---|---|---|---|---|---|---|
| | | example C1 | example C2 | example C3 | example C4 | example C5 | example C6 |
| SiO₂ | | 72 | 73.5 | 72.7 | 73.5 | 73 | 73.5 |
| Al₂O₃ | | 9 | 5.5 | 7 | 8 | 7.5 | 7.5 |
| P₂O₅ | | 3 | 3.5 | 2.3 | 3.3 | 2.8 | 2.5 |
| B₂O₃ | | 0.5 | 0.5 | 0.3 | 1 | 0.5 | 0 |
| Li₂O | | 11 | 11 | 12.5 | 9 | 11 | 10.4 |
| Na₂O | | 1 | 1.2 | 1.4 | 1.2 | 1 | 0.8 |
| CaO | | 0.5 | 0.6 | 0.8 | 0.6 | 1.6 | 0.6 |
| ZrO₂ | | 3 | 4.2 | 3 | 3.4 | 2.6 | 4.7 |
| A | | −4 | 18.5 | 5.7 | 7.5 | 6 | 7.7 |
| B | | 0.33 | 0.71 | 1.04 | 0.15 | 0.65 | 0.40 |
| C₃ | | 1.00 | 1.20 | 1.10 | 1.22 | 0.43 | 1.64 |
| Microcrys- | Li₂Si₂O₅/% | 31 | 13 | 35 | 25 | 54 | 16 |
| talline glass | LiAlSi₄O₁₀/% | 37 | 18 | 38 | 28 | 15 | 52 |
| | Crystal | 122 | 65 | 145 | 68 | 136 | 113 |
| | size nm | | | | | | |
| | Total | 68 | 31 | 73 | 53 | 69 | 68 |
| | crystalline | | | | | | |
| | phase | | | | | | |
| | content | | | | | | |
| | b value | 1.66 | 0.38 | 3.38 | 0.43 | 1.82 | 1.52 |
| | Transmit- | 88.6 | 91.5 | 86.2 | 91.4 | 88.2 | 88.8 |
| | tance % of | | | | | | |
| | 0.7 mm | | | | | | |
| | microcrys- | | | | | | |
| | talline | | | | | | |
| | glass at | | | | | | |
| | 560 nm | | | | | | |
| | Haze % | 0.42 | 0.13 | 0.85 | 0.12 | 0.35 | 0.41 |
| Chemically- | Li₂Si₂O₅/% | 29 | 6 | 31 | 15 | 29 | 9 |
| strengthened | LiAlSi₄O₁₀/% | 34 | 10 | 33 | 17 | 8 | 25 |
| microcrys- | Total | 63 | 16 | 64 | 32 | 37 | 34 |
| talline glass | crystalline | | | | | | |
| | phase | | | | | | |
| | content | | | | | | |

| | | | | | | |
|---|---|---|---|---|---|---|
| 180-mesh sandpaper | 210 | 100 | 210 | 135 | 160 | 150 |
| drop height/cm | | | | | | |

TABLE III4
Process parameter and performance of microcrystalline glass
prepared by glass composition in Embodiments C1 and C8

| | | Glass composition of | | | | Glass composition of | | | |
|---|---|---|---|---|---|---|---|---|---|
| | | Embodiment C1 | | | | Embodiment C8 | | | |
| Treatment | First | 20 min, | 60 min, | 40 min, | 40 min, | 20 min, | 40 min, | 60 min, | 40 min, |
| system | nucleation | 510° C., | 510° C., | 540° C., | 540° C., | 510° C., | 510° C., | 540° C., | 540° C., |
| | treatment | 3 h | 8 h | 3 h | 8 h | 3 h | 8 h | 3 h | 8 h |
| | Second | 5 min, | 30 min, | 17 min, | 16 min, | 5 min, | 17 min, | 5 min, | 30 min, |
| | nucleation | 580° C., | 580° C., | 610° C., | 610° C., | 580° C., | 580° C., | 610° C., | 610° C., |
| | treatment | 3 h | 8 h | 3 h | 8 h | 3 h | 8 h | 3 h | 8 h |
| | Crystallization | 30 min, | 5 min, | 16 min, | 17 min, | 30 min, | 30 min, | 15 min, | 16 min, |
| | treatment | 650° C., | 650° C., | 680° C., | 680° C., | 650° C., | 650° C., | 680° C., | 680° C., |
| | | 3 h | 8 h | 3 h | 8 h | 3 h | 8 h | 3 h | 8 h |
| Crystalline | Li₂Si₂O₅/% | 32 | 38 | 35 | 43 | 38 | 42 | 41 | 45 |
| phase | LiAlSi₄O₁₀/% | 33 | 42 | 36 | 45 | 38 | 43 | 40 | 45 |

| | | | | | | | | |
|---|---|---|---|---|---|---|---|---|
| Crystal | 76 | 89 | 84 | 93 | 76 | 85 | 79 | 92 |
| size nm | | | | | | | | |
| Total crystalline | 65 | 80 | 71 | 88 | 76 | 85 | 81 | 90 |
| phase content | | | | | | | | |
| b value after | 0.39 | 0.41 | 0.41 | 0.42 | 0.32 | 0.33 | 0.34 | 0.35 |
| heat treatment | | | | | | | | |
| Haze % | 0.16 | 0.18 | 0.17 | 0.19 | 0.11 | 0.12 | 0.12 | 0.13 |
| Transmittance | 91.2 | 91.1 | 91.1 | 91 | 91.7 | 91.5 | 91.6 | 91.5 |
| % of 0.7 mm | | | | | | | | |
| microcrystalline | | | | | | | | |
| glass at 560 nm | | | | | | | | |

The time for the first nucleation treatment, the second nucleation treatment, and crystallization treatment represented the time for heating, the temperature represented a target heating temperature, and the time represented a treatment time.

TABLE III5
Process parameter and performance of the chemically-strengthened microcrystalline
glass prepared by glass composition in Embodiments C1 and C8
Glass composition of Embodiment C1

| | | | | | | | | | |
|---|---|---|---|---|---|---|---|---|---|
| Chemical | Molten | NaNO₃ | NaNO₃ | NaNO₃ | NaNO₃ | NaNO₃ | NaNO₃ | NaNO₃ | NaNO₃ |
| strength- | salt | 40%, | 40%, | 40%, | 40%, | 20%, | 20%, | 20%, | 20%, |
| ening | concen- | KNO₃6 | KNO₃6 | KNO₃6 | KNO₃6 | KNO₃8 | KNO₃8 | KNO₃8 | KNO₃8 |
| system | tration | 0% | 0% | 0% | 0% | 0% | 0% | 0% | 0% |
| | Strength- | 500° C., | 500° C., | 420° C., | 420° C., | 420° C., | 420° C., | 500° C., | 500° C., |
| | ening | 8 h | 3 h | 8 h | 3 h | 3 h | 8 h | 3 h | 8 h |
| | temperature, | | | | | | | | |
| | time | | | | | | | | |

| | | | | | | | | |
|---|---|---|---|---|---|---|---|---|
| 180-mesh sandpaper | 200 | 225 | 220 | 230 | 235 | 225 | 230 | 210 |
| drop height/cm | | | | | | | | |

Glass composition of Embodiment C8

| | | | | | | | | | |
|---|---|---|---|---|---|---|---|---|---|
| Chemical | Molten | NaNO₃ | NaNO₃ | NaNO₃ | NaNO₃ | NaNO₃ | NaNO₃ | NaNO₃ | NaNO₃ |
| strength- | salt | 40%, | 40%, | 40%, | 40%, | 20%, | 20%, | 20%, | 20%, |
| ening | concen- | KNO₃6 | KNO₃6 | KNO₃6 | KNO₃6 | KNO₃8 | KNO₃8 | KNO₃8 | KNO₃8 |
| system | tration | 0% | 0% | 0% | 0% | 0% | 0% | 0% | 0% |
| | Strength- | 500° C., | 500° C., | 420° C., | 420° C., | 420° C., | 420° C., | 500° C., | 500° C., |
| | ening | 8 h | 3 h | 8 h | 3 h | 3 h | 8 h | 3 h | 8 h |
| | temperature, | | | | | | | | |
| | time | | | | | | | | |

| | | | | | | | | |
|---|---|---|---|---|---|---|---|---|
| 180-mesh sandpaper | 235 | 250 | 245 | 255 | 260 | 250 | 255 | 245 |
| drop height/cm | | | | | | | | |

From performance test results of the microcrystalline glass of various embodiments shown in Table III1, Table III2, Table III4, and Table III5, it might be seen that, by using the Embodiments C1-C16 of the technical solutions of the present disclosure, the lithium disilicate Li₂Si₂O₅ in the chemically-strengthened microcrystalline glass was greater than 30%, the petalite LiAISi₄O₁₀ was greater than 30%, the total crystalline phase of the microcrystalline glass and the total crystalline phase of the chemically-strengthened microcrystalline glass were both 60%-90%, the average crystal size of the crystal particle in the microcrystalline glass was less than 100 nm, the visible light transmittance of the 0.7 mm microcrystalline glass was greater than 91%, and the drop resistance height was greater than 200 cm.

From Table III3, it might be seen that, in Comparative example C1, Al₂O₃=9%, A=−4, and C₃₌₁, failing to meet requirements of the glass composition of the present disclosure, the microcrystalline phase content in the heat-treated microcrystalline glass was less, crystal size >100 nm; the transmittance was low, the b value was too large, and the haze was large.

In Comparative example C₂, Al₂O₃=5.5%, A=18.5, and C₃=1.2, failing to meet requirements of the glass composition of the present disclosure, the microcrystalline phase content in the heat-treated microcrystalline glass was less, and drop resistance was relatively poor.

In Comparative example C₃, Li₂O=12.5%, B=1.04, and C₃=1.1, failing to meet requirements of the glass composition of the present disclosure, the size of the heat-treated microcrystalline glass was greater than 100 nm; and the transmittance was low, the b value was too large, and the haze was large.

In Comparative example C₄, Li₂O=9%, B=0.15, and C₃=1.22, failing to meet requirements of the glass composition of the present disclosure, the crystalline phase content in the chemically-strengthened microcrystalline glass was less, and drop resistance was relatively poor.

In Comparative example C₅, CaO=1.6%, ZrO₂=2.6%, and C₃=0.43, failing to meet requirements of the glass composition of the present disclosure, the size of the heat-treated microcrystalline glass was greater than 100 nm; the transmittance was low, the b value was too large, the haze was large; and the crystalline phase content in the chemically-strengthened microcrystalline glass was less, and drop resistance was relatively poor.

In Comparative example C₆, B2O₃₌₀, and C₃=1.64, failing to meet requirements of the glass composition of the present disclosure, the size of the heat-treated microcrystalline glass was greater than 100 nm; the transmittance was low, the b value was too large, the haze was large; and the crystalline phase content in the chemically-strengthened microcrystalline glass was less, and drop resistance was relatively poor.

Compared to the reduction in the total crystalline phase content of the microcrystalline glass relative to the chemically-strengthened microcrystalline glass in the comparative examples, the reduction in the total crystalline phase content of the microcrystalline glass relative to the chemically-strengthened microcrystalline glass in the embodiments of the present disclosure was less, it indicated that the situations of a reduced crystal content and a damaged interlocking structure of two crystalline phases occurred in the microcrystalline glass in the embodiments of the present disclosure during the chemical strengthening process were significantly improved, and the strengthening performance of the obtained the chemically-strengthened microcrystalline glass was excellent.

The above are merely the preferred embodiments of the present disclosure, and are not intended to limit the scope of the patent for the present disclosure. For those skilled in the art, the present disclosure may have various modifications and variations. Any modifications, equivalent replacements, improvements and the like made within the spirit and principle of the present disclosure shall fall within the scope of patent protection of the present disclosure.

What is claimed is:

1. A glass composition comprising the following components by mass percentage:
72-74.3% of SiO₂, 7-8.5% of Al₂O₃, 1.8-3% of P₂O₅, 10.2-12.5% of Li₂O, 0.5-2% of Na₂O and 3.5-4.7% of ZrO₂;
2.9≤W(SiO₂)-6×W(Al₂O₃)-2×W(Li₂O)≤5.2;
0.26≤[W(Li₂O)—W(Al₂O₃)]/[W(P₂O₅)+W(ZrO₂)]≤0.85;
1.17≤W(ZrO₂)/W(P₂O₅)≤2.61; and
2.5≤[W(SiO₂)-6×W(Al₂O₃)-2×W(Li₂O)]/W(Na₂O)≤5.8.

2. (canceled)

3. The glass composition according to claim 1, comprising the following components by mass percentage:
72.8-73.9% of SiO₂, 7.4-8% of Al₂O₃, 2.1-2.6% of P₂O₅, 10.7-11.7% of Li₂O, 0.9-1.4% of Na₂O and 3.9-4.4% of ZrO₂;
preferably, 4.5≤W(SiO₂)-6×W(Al₂O₃)-2×W(Li₂O)≤5.2;
0.42≤[W(Li₂O)—W(Al₂O₃)]/[W(P₂O₅)+W(ZrO₂)]≤0.66;
1.5≤W(ZrO₂)/W(P₂O₅)≤2.1; and
3.57≤[W(SiO₂)-6×W(Al₂O₃)-2×W(Li₂O)]/W(Na₂O)≤5.

4. (canceled)

5. A microcrystalline glass comprising the glass composition according to claim 1, wherein the microcrystalline glass comprises a crystalline phase Li₂Si₂O₅ and a crystalline phase LiAlSi₄O₁₀;
preferably, 0.91≤W(Li₂Si₂O₅)/W(LiAlSi₄O₁₀)≤1.06;
preferably, 0.97≤W(Li₂Si₂O₅)/W(LiAlSi₄O₁₀)≤1.03;
preferably, 10.44≤M≤12.54, wherein
M=1.3×[W(Li₂Si₂O₅)/W(LiAlSi₄O₁₀)]×{0.86×[W(SiO₂)-6×W(Al₂O₃)-2×W(Li₂O)]+1.83×[(W(Li₂O)—W(Al₂O₃))/(W(P₂O₅)+W(ZrO₂))]+1.67×[W(ZrO₂)/W(P₂O₅)]+0.25×[(W(SiO₂)-6×W(Al₂O₃)-2×W(Li₂O))/W(Na₂O)]};
preferably, 11.85≤M≤12.54.

6. (canceled)

7. (canceled)

8. (canceled)

9. (canceled)

10. A method for preparing a microcrystalline glass, comprising the following steps:
weighing the glass composition according to claim 1;
mixing the glass composition, then melting, clarifying, homogenizing, molding, annealing, and finally cutting to obtain a basic glass; and
heat treating on the basic glass to obtain microcrystalline glass.

11. The method for preparing the microcrystalline glass according to claim 10, wherein the step of heat treating on the basic glass to obtain the microcrystalline glass comprises:
heating the basic glass from a room temperature to 530-570° C. in 20-60 min, and nucleation treating for over 3 h;
heating a temperature to 680-720° C. in 5-30 min, and crystallization treating for over 3 h; and
cooling the temperature to the room temperature to obtain the microcrystalline glass;
preferably, after the step of heat treating on the basic glass to obtain the microcrystalline glass, the method further comprises:
providing an ion exchange bath, wherein the ion exchange bath comprises, by mass percentage, 20-40% of NaNO₃ and 60-80% of KNO₃; and
pre-treating the microcrystalline glass, and then placing same into the ion exchange bath for a salt bath, so as to obtain a chemically-strengthened microcrystalline glass, wherein a strengthening temperature of the salt bath was 420-500° C., and a strengthening time of the salt bath was 3-8 h;
preferably, in the step of mixing the glass composition, then melting, clarifying, homogenizing, molding, annealing, and finally cutting to obtain the basic glass, a molding method comprises a float molding, an overflow molding, a calendaring molding, or a slit pull-down molding.

12. (canceled)

13. (canceled)

14. An electronic display terminal, comprising the microcrystalline glass according to claim 5.

15. A glass composition, comprising the following components by mass percentage:
72-74% of SiO₂, 7.5-8.4% of Al₂O₃, 2-2.8% of P₂O₅, 0.3-0.8% of B2O₃, 10.5-11.8% of Li₂O, 0.5-1.3% of Na₂O and 3.4-4.7% of ZrO₂.

16. The glass composition according to claim 15, wherein—1.1≤W(SiO₂)-6×W(Al₂O₃)-2×W(Li₂O)≤6.7;
preferably, 0.19≤[W(Li₂O)—W(Al₂O₃)]/[W(P₂O₅)+W(ZrO₂)]≤0.98;
preferably, 0.06≤[W(ZrO₂)-3×W(B2O₃)]/W(P₂O₅)≤1.57;
preferably, 0.6≤W(SiO₂)-6×W(Al₂O₃)-2×W(Li₂O)≤5.4;
0.28≤[W(Li₂O)—W(Al₂O₃)]/[W(P₂O₅)+W(ZrO₂)]≤0.8; and
0.5≤[W(ZrO₂)-3×W(B2O₃)]/W(P₂O₅)≤1.36;
preferably, 72.5-73.5% of SiO₂, 7.7-8% of Al₂O₃, 2.1-2.5% of P₂O₅, 0.5-0.7% of B2O₃, 11-11.5% of Li₂O, 0.7-1.1% of Na₂O and 3.8-4.4% of ZrO₂;
preferably, 2.5≤W(SiO₂)-6×W(Al₂O₃)-2×W(Li₂O)≤4.3;
0.43≤[W(Li₂O)—W(Al₂O₃)]/[W(P₂O₅)+W(ZrO₂)]≤0.64; and
0.81≤[W(ZrO₂)-3×W(B2O₃)]/W(P₂O₅)≤1.16.

17. (canceled)

18. (canceled)

19. (canceled)

20. (canceled)

21. (canceled)

22. (canceled)

23. A microcrystalline glass comprising the glass composition according to claim 15;
preferably, a thickness of the microcrystalline glass is 0.3-1.5 mm.

24. (canceled)

25. A method for preparing a microcrystalline glass, comprising the following steps:
weighing the glass composition according to claim 15;
mixing the glass composition, then melting, clarifying, homogenizing, molding, annealing, and finally cutting to obtain a basic glass; and
heat treating on the basic glass to obtain the microcrystalline glass.

26. The method for preparing the microcrystalline glass according to claim 25, wherein the step of heat treating on the basic glass to obtain the microcrystalline glass comprises:
heating the basic glass from a room temperature to 510-540° C. in 20-60 min, and performing a first nucleation treatment, wherein a time for the first nucleation treatment is 3-8 h;
heating a temperature to 580-610° C. in 5-30 min, and performing a second nucleation treatment, wherein a time for the second nucleation treatment is 3-8 h;
heating the temperature to 650-680° C. in 5-30 min, and performing a crystallization treatment, wherein the time for the crystallization treatment is 3-8 h; and
cooling a temperature to the room temperature to obtain the microcrystalline glass;
preferably, after the step of heat treating on the basic glass to obtain the microcrystalline glass, the method further comprises:
pre-treating the microcrystalline glass, and then placing same into an ion exchange bath for a salt bath, so as to obtain a chemically-strengthened microcrystalline glass, wherein
the ion exchange bath comprises, by mass percentage, 20-40% of NaNO₃ and 60-80% of KNO₃; and/or
a strengthening temperature of the salt bath is 420-500° C.; and/or
a strengthening time of the salt bath is 3-8 h;
preferably, in the step of mixing the glass composition, then melting, clarifying, homogenizing, molding, annealing, and finally cutting to obtain the basic glass, a molding method comprises a float molding, an overflow molding, a calendaring molding, or a slit pull-down molding.

27. (canceled)

28. (canceled)

29. An electronic display terminal comprising the microcrystalline glass according to claim 23.

30. A glass composition comprising the following components by mass percentage based on oxides:
71.5-74% of SiO₂, 6.2-8.5% of Al₂O₃, 1.7-2.6% of P₂O₅, 0.1-1.7% of B2O₃, 10-12% of Li₂O, 0.1-2% of Na₂O, 0.1-1.5% of CaO and 3-5% of ZrO₂.

31. The glass composition according to claim 30, comprising the following components by mass percentage based on oxides:
72-73.5% of SiO₂, 6.8-8.2% of Al₂O₃, 2-2.4% of P₂O₅, 0.4-1.1% of B2O₃, 10.8-11.7% of Li₂O, 0.4-1.7% of Na₂O, 0.3-1% of CaO and 3.3-4.4% of ZrO₂;
preferably, 2≤[W(ZrO₂)—W(CaO)]/[W(P₂O₅)—W(B2O₃)]≤3.22;
preferably, 2.06≤[W(ZrO₂)—W(CaO)]/[W(P₂O₅)—W(B2O₃)]≤2.31;
preferably, 2.3≤W(SiO₂)-6×W(Al₂O₃)-2×W(Li₂O)≤10.3; and
0.27≤[W(Li₂O)—W(Al₂O₃)]/[W(P₂O₅)+W(ZrO₂)]≤0.87;
preferably, 2.7≤W(SiO₂)-6×W(Al₂O₃)-2×W(Li₂O)≤7.8; and
0.46≤[W(Li₂O)—W(Al₂O₃)]/[W(P₂O₅)+W(ZrO₂)]≤0.77.

32. (canceled)

33. (canceled)

34. (canceled)

35. (canceled)

36. A microcrystalline glass comprising the glass composition according to claim 30.

37. The microcrystalline glass according to claim 36, wherein a crystalline phase of the microcrystalline glass mainly is a lithium disilicate and a petalite, and a total content of the crystalline phase of the microcrystalline glass is 60%-90%, a content of the lithium disilicate is greater than 30%, and a content of the petalite is greater than 30%.

38. A method for preparing a microcrystalline glass, comprising the following steps:
weighing the glass composition according to claim 30;
mixing the glass composition, then melting, clarifying, homogenizing, molding, annealing, and finally cutting to obtain a basic glass; and
heat treating on the basic glass to obtain the microcrystalline glass; and
pre-treating the microcrystalline glass, and then placing same into an ion exchange bath for a salt bath, so as to obtain a chemically-strengthened microcrystalline glass.

39. The method for preparing the microcrystalline glass according to claim 38, wherein the ion exchange bath comprises, by mass percentage, 20-40% of NaNO₃ and 60-80% of KNO₃, a strengthening temperature of the salt bath is 420-500° C., and a strengthening time of the salt bath is 3-8 h.

40. The method for preparing the microcrystalline glass according to claim 38, wherein the step of heat treating on the basic glass to obtain the microcrystalline glass comprises:
heating the basic glass from a room temperature to 510-540° C. in 20-60 min, and performing a first nucleation treatment, wherein a time for the first nucleation treatment is 3-8 h;
heating a temperature to 580-610° C. in 5-30 min, and performing a second nucleation treatment, wherein a time for the second nucleation treatment is 3-8 h;
heating the temperature to 650-680° C. in 5-30 min, and performing a crystallization treatment, wherein a time for the crystallization treatment is 3-8 h; and
cooling the temperature to the room temperature to obtain the microcrystalline glass;
preferably, in the step of mixing the glass composition, then melting, clarifying, homogenizing, molding, annealing, and finally cutting to obtain the basic glass, a molding method comprises a float molding, an overflow molding, a calendaring molding, or a slit pull-down molding.

41. (canceled)

42. An electronic display terminal comprising the microcrystalline glass according to claim 36.
